(19) United States
(12) Patent Application Publication
(10) Pub. No.: US 2017/0085246 A1
(43) Pub. Date: Mar. 23, 2017

(54) Tunable surface acoustic wave resonators and filters

(71) Applicants: Ishiang Shih, Brossard (CA); Cindy X. Qiu, Brossard (CA); Chunong Qiu, Brossard (CA); Andy Shih, Brossard (CA); Julia Qiu, Brossard (CA); Yi-Chi Shih, Brossard (CA)

(72) Inventors: Ishiang Shih, Brossard (CA); Cindy X. Qiu, Brossard (CA); Chunong Qiu, Brossard (CA); Andy Shih, Brossard (CA); Julia Qiu, Brossard (CA); Yi-Chi Shih, Brossard (CA)

(21) Appl. No.: 14/756,554

(22) Filed: Sep. 17, 2015

(51) Int. Cl. H03H 9/145; H03H 9/25

(52) U.S. Cl. CPC H03H 9/145; H03H 9/25

(57) ABSTRACT

Filters and oscillators are important components for electronic systems especially those for communications. For many portable units operating at 2 GHz or less, surface acoustic wave resonators are used as filters or oscillators, the resonant frequency is determined by the electrode pitch and velocity of the surface acoustic waves. Because of the large number of frequency bands for communications, it is important to have SAW resonators where the resonant frequencies are tunable and adjustable. This invention provides tunable surface acoustic wave resonators utilizing semiconducting piezoelectric layers having embedded or elevated electrode doped regions. Both metallization ratio and loading mass are changed by varying a DC biasing voltage to effect a change in the resonant frequency. A plurality of the present tunable SAW devices may be connected into a tunable and selectable microwave filter for selecting and adjusting of the bandpass frequency or an tunable oscillator by varying the DC biasing voltages.

### FIELD OF THE INVENTION

This invention relates to tunable and adjustable filtering of frequency and generation of frequency of RF signals for communication systems. More specifically, it relates to tunable and adjustable piezoelectric semiconductor filters with embedded electrode doped regions or with elevated electrode doped region.

### BACKGROUND OF THE INVENTION

Electronic systems especially those operate at radio frequencies (RF) for communication applications require small bandpass filters and oscillators. The oscillators are for generation of frequency signals whereas the bandpass filters are to select transmit or receive signals within certain band width BW at a given frequency. Some examples of the systems include global positioning systems (GPS), mobile telecommunication systems: Global Systems for Mobile Communications (GSM), personal communication service (PCS), the Universal Mobile Telecommunications System (UMTS), Long Term Evolution Technology (LTE), and some data transfer units: Bluetooth, Wireless Local Area Network (WLAN), satellite broadcasting and future traffic control communications. They also include other high frequency systems for air and space vehicles.

There are few types of bandpass filters and oscillators that are fabricated using different technologies: (a) ceramic filters or oscillators based on dielectric resonators; (b) filters or resonators using surface acoustic wave resonators (SAW), and (c) filters oscillators using thin film bulk acoustic wave resonators (FBAR). Both SAW and FBAR are used when dimensions of the systems are limited. Currently, SAW devices are used in volume applications at frequencies below 2 GHz while FBARs are dominant in systems at frequencies between 2 GHz and 4 GHz. For mobile communication systems such as handsets, the power capability required for the RF filters is about 5 W or less which is not too large, but the size and cost requirements are quite critical. Because of this and due to its large volume, the RF filters in handsets are usually manufactured by microelectronic fabrication processes on piezoelectric materials such as LiNbO₃ (for SAWs) or AlN (for FBARs).

Since this invention relates to tunable and adjustable SAW devices, in the introductory section a description will be made only on a SAW devices. The development of SAW dated back to 1965, when the first SAW devices were made. Earlier research work in SAW devices was mainly to fulfill the needs of radar signal processing. In the 1980s and 1990s, the main development efforts were on low loss filters particularly for mobile phones. In addition to the electronic applications as filters or oscillators, there are other applications for SAWs, namely non-destructive evaluation, seismology, acoustic-optics, acoustic microscope and sensors. An account on several main developments till 1998 in this area has been given in “History of SAW Devices” 1998 IEEE International Frequency Control Symposium, pp. 439-460, by David P. Morgan. Various SAW structures and innovations have been developed in the last decades especially for communications. A summary of these SAW structures have been described in “Evolution of the SAW Transducer for Communication Systems” 2004 IEEE International Ultrasonics, Ferroelectrics, and Frequency Control Joint 50th Anniversary Conference, pp. 302-310, by Donald C. Malocha. The main SAW structures include (a) fundamental and unweighted devices, (b) apodization devices, (c) phase coding and various weighting and (d) single phase unidirectional device.

The main properties of piezoelectric materials for filters are propagation velocity of acoustic waves which determines the resonant frequency along with electrode pitch and the coupling coefficients which affect the band width. The basic principles of SAW devices can be understood by considering a basic SAW structure as shown in FIG. 1 where a schematic diagram of a prior art surface acoustic wave filter (100a) on a piezoelectric substrate (110) is shown. SAW (100) comprises an input inter digital transducer IDT1 (120) with a center-to-center distance between adjacent electrodes controlled to a “pitch” and an output inter digital transducer IDT2 (150) with a center-to-center distance between adjacent electrodes also controlled to the “pitch”. The IDT1 (120) is connected to an electrical signal source (130) to excite acoustic waves (140) with a velocity v and a frequency f₀=v/(2×pitch). The IDT2 (150) is to receive the acoustic waves (140) and convert them into an output electrical signal (160). Electrical signals in the signal source (130) at frequencies other than f₀ can not excite resonant acoustic waves with sufficient level to reach the output inter digital transducer IDT2 (150) to generate an output signal in the output terminals. Therefore, once a SAW filter has been fabricated, the central frequency f₀ of transmission and bandwidth BW are fixed by the geometry and materials used. Only the electrical signals at f₀ and within the bandwidth BW are allowed to reach the output inter digital transducer (150) from the input inter digital transducer (120).

Velocities of acoustic waves in piezoelectric materials are important for designing acoustic filters. Values for several piezoelectric substrates are given here: ˜4,000 m/s for LiNbO₃, ˜6,300 m/s for ZnO, ˜10,400 m/s for AlN and ˜7,900 m/s for GaN. To obtain a filter on LiNbO₃ with a central frequency f₀=2 GHz, the acoustic wave wavelength is λ=(4000 msec)/(2×10⁹/sec)=2×10⁴ cm. The value of electrode pitch in FIG. 1 is then equal to 1 μm. Assume that the width of electrodes and space between adjacent electrodes are equal, then the electrode width is 0.5 μm. To fabricate IDTs at higher frequencies, more advanced lithography tools and more severe processing control will be needed and/or piezoelectric materials with high velocities of acoustic waves such as ZnO, GaN and AlN must be used.

For each communication band, there are two frequencies: one for transmitting and the other for receiving, which are often close to each other. Take mobile phone communications as examples, the frequencies and bandwidths of RF signals for communications have been defined and assigned by regions or countries. For mobile communications, there are currently about 40 bands or frequency ranges. More bands in the frequency range of 3 to 6 GHz are expected for the next generation long term extension technology. Table 1 lists several selected bands for mobile communications used in different regions or countries. In each band there is a transmit band (Tx Band) at f_{0TR} with a transmit band width (BW_{TR}). There is also an associated receive band (Rx Band) at f_{0RE} with a receive band width (BW_{RE}). The separation between the transmit band and receive band is given by the difference between f_{0RE} and f_{0TR}:f_{0RE}−f_{0TR}. Here, f_{0TR} is the transmit band central frequency and f_{0RE} is the receive band central frequency.

TABLE 1
Band frequencies and band width for some of the Bands assigned to mobile handsets
and base stations.

| | f_{oTR} | BW_{TR} | f_{oRE} | BW_{RE} | f_{oRE} − f_{oTR} | | |
|---|---|---|---|---|---|---|---|
| Band | (MHz) | (MHz) | (MHz) | (MHz) | (MHz) | [f_{oRE} − f_{oTR}]/f_{oTR} | Region |
| 1 | 1920-1980 | 60 | 2110-2170 | 60 | 190 | 9.8% | Asia, EMEA, Japan |
| 2 | 1850-1910 | 60 | 1930-1990 | 60 | 80 | 4.3% | N. America, Latin Am. |
| 3 | 1710-1785 | 75 | 1805-1880 | 75 | 95 | 5.4% | Asia, EMEA |
| 4 | 1710-1755 | 45 | 2110-2155 | 45 | 400 | 23% | N. America, Latin Am. |
| 5 | 824-849 | 25 | 869-894 | 25 | 45 | 5.4% | N. America, Latin Am. |
| 7 | 2500-2570 | 70 | 2620-2690 | 70 | 120 | 4.7% | Asia, EMEA |
| 8 | 880-915 | 35 | 925-960 | 35 | 45 | 5.0% | EMEA, Latin Am. |
| 12 | 699-716 | 17 | 729-746 | 17 | 30 | 4.2% | N. America |

There are several wireless standards used in different countries and regions. The main ones are briefly described below.

Global System for Mobile Communications (GSM) is a standard developed by the European Telecommunication Standards Institute to provide protocols for 2G digital cellular networks for mobile phones and is first deployed in 1992 in Finland. Personal Communication Service (PCS) describes a set of 3G wireless communication capabilities which allows certain terminal mobility, personal mobility and service management. In Canada, the United States and Mexico, PCS are provided in 1.9 GHz band (1.850-1.990 GHz) to expand the capacity originally provided by the 850 MHz band (800-894 MHz). These bands are particular to the North America although other frequency bands are also used. The Universal Mobile Telecommunications System (UMTS) is a 3G mobile cellular system for networks based on the GSM standard. UMTS uses wideband code division multiple access (W-CDMA) radio access technology to offer greater spectral efficiency and bandwidth to mobile network operators. Long-Term Evolution (LTE) is a 4G standard for wireless communication with high-speed data for mobile phones and data terminals. It is an upgrade based on the GSM and UMTS network technologies. Different LTE frequencies and bands from about 1 GHz to 3 GHz are used in different countries and regions. There are unlicensed bands in the range of 3 GHz to 6 GHz which maybe used in the near future for mobile communications to increase capacity. Therefore, mobile phones must be equipped with multiple bands modules in order to be used in different countries and regions.

Due to the large number of bands used in the mobile handsets in different regions and countries, and even in the same country, a practical handset needs to have an RF front end covering several frequency bands. A true world phone will need to have about 40 bands, each with a transmit band and receive band. As each RF filter has only one central frequency of resonant and a bandwidth which are fixed, therefore, such a true world phone will need to have 80 filters for the front end. Due to the resource limitations, some designers design mobile phone handsets to cover 5 to 10 bands for selected regions or countries. Even with this reduced number of bands, the number of RF filters currently required is still large: 10˜20 units. Therefore, there are strong needs to reduce the dimensions and cost of the RF filters and to reduce the number of filters for the same number of operation bands by having tunable RF filters, each to cover at least two frequency bands. If this is successful, the number of filters can be reduced in the mobile handsets and many other microwave and wireless systems.

Thus, it would be ideal to develop an RF filter which can cover as many bands or frequency ranges as possible so that the size and power consumption of RF front ends in a mobile phone handset and microwave systems can be reduced. In Table 1, values of [f_{0RE}−f_{0TR}]/f_{0TR} are listed. It is seen that for 11 bands out of the 12 bands listed, [f_{0RE}−f_{0TR}]/f_{0TR} has a value of 10% of less: mostly ˜5%. Therefore, tunable filters with a tuning range of 10% or more will be highly valuable for communications.

### BRIEF SUMMARY OF THE INVENTION

One object of the invention is to provide tunable SAW inter digital transducers having embedded positive electrode doped regions and embedded negative electrode doped regions for SAW RF resonators, filters, oscillators, switches or duplexers with the central frequency of resonant or transmission tunable by the application of a DC voltage for the construction of wireless or microwave systems, where the doping type of the embedded positive electrode doped regions is different from the doping type of the embedded negative electrode doped regions.

One other object of the invention is to provide a tunable SAW inter digital transducer with embedded positive electrode doped regions and embedded negative electrode doped regions for SAW RF resonators, filters, oscillators, switches or duplexers with the central frequency of resonant or transmission tunable by the application of a DC voltage for the construction wireless or microwave systems where the doping type of the embedded positive electrode doped regions is the same as the doping type of the embedded negative electrode doped regions.

Another object of the invention is to provide a tunable SAW inter digital transducer with elevated positive electrode doped regions and elevated negative electrode doped regions for SAW RF resonators, filters, oscillators, switches or duplexers with the central frequency of resonant or transmission tunable by the application of a DC voltage for the construction wireless or microwave systems, where the doping type of the elevated positive electrode doped regions is different from the doping type of the elevated negative electrode doped regions.

Yet another object of the invention is to provide a tunable SAW inter digital transducer with elevated positive electrode doped regions and elevated negative electrode doped regions for SAW RF resonators, filters, oscillators, switches or duplexers with the central frequency of resonant or transmission tunable by the application of a DC voltage for the construction wireless or microwave systems, where the doping type of the elevated positive electrode doped regions is the same as the doping type of the elevated negative electrode doped regions.

### BRIEF DESCRIPTION OF THE SEVERAL VIEWS OF THE DRAWINGS

FIG. 1 shows a schematic diagram of a prior art surface acoustic wave filter (100) on a piezoelectric substrate having an input inter digital transducer IDT1 to excite surface acoustic waves and an output inter digital transducer IDT2 to receive the surface acoustic waves and covert them into an output electrical signal.

FIG. 2A is a schematic top view showing a SAW filter (200a) with tunable frequency according to this invention. An input inter digital transducer IDT1 is connected to an input DC biasing voltage to adjust the frequency of the excited surface acoustic waves and an output inter digital transducer IDT2 is connected to an output DC biasing voltage to adjust the frequency of the surface acoustic waves to be received.

FIG. 2B is a schematic top view showing a SAW filter (200b) with tunable frequency according to this invention. An input inter digital transducer IDT1 is connected to an input DC biasing voltage to adjust the frequency of the excited surface acoustic waves and an output inter digital transducer IDT2 is connected to an output DC biasing voltage to adjust the frequency of the surface acoustic waves to be received.

FIG. 2C is a schematic cross-sectional view taken along line A-A′ in the tunable SAW filter (200a) in FIG. 2A or (200b) in FIG. 2B, showing a part of the input inter digital transducer IDT1 having an embedded input positive electrode doped region and an embedded input negative electrode doped region without an input DC biasing voltage.

FIG. 2D is a schematic cross-sectional view taken along line B-B′ in the tunable SAW filter (200a) in FIG. 2A or (200b) in FIG. 2B, showing a part of the output inter digital transducer IDT2 having an embedded output positive electrode doped region and an embedded output negative electrode doped region without an output DC biasing voltage.

FIG. 2E is a schematic cross-sectional view taken along line A-A′ in the tunable SAW filter (200a) in FIG. 2A or (200b) in FIG. 2B, showing a part of IDT1 with embedded input positive and negative electrode doped regions. A first input DC biasing voltage V_{DC1} is applied to create an input positive electrode depletion region and an input negative electrode depletion region, reduce the mass loading associated with the electrode doped neutral regions and increase the frequency of the surface acoustic waves to be excited.

FIG. 2F is a schematic cross-sectional view taken along line B-B′ in the tunable SAW filter (200a) in FIG. 2A or (200b) in FIG. 2B, showing a part of IDT2 with embedded output positive and negative electrode doped regions. A first output DC biasing voltage V_{DC1′} is applied to create an output positive electrode depletion region and an output negative electrode depletion region, reduce the mass loading associated with the electrode doped neutral regions and increase the frequency of the surface acoustic waves to be received.

FIG. 2G is a schematic cross-sectional view showing a part of IDT1 with embedded input positive and negative electrode doped regions. A second input DC biasing voltage V_{DC2} is applied to create an input positive electrode depletion region and an input negative electrode depletion region with larger thicknesses in order to decrease further the mass loading associated with the electrode doped neutral regions and to increase further the frequency of the surface acoustic waves to be excited.

FIG. 2H is a schematic cross-sectional view showing a part of IDT2 with embedded output positive and negative electrode doped regions. A second output DC biasing voltage V_{DC2′} is applied to create an output positive electrode depletion region and an output negative electrode depletion region with larger thicknesses in order to decrease further the mass loading associated with the electrode doped neutral regions and to increase further the frequency of the surface acoustic waves to be received.

FIG. 2I is a cross-section view of an input inter digital transducer IDT1 with a temperature compensation layer to reduce the change of surface acoustic wave frequency with the change of temperature.

FIG. 3A shows the variation of electric field ξ(x) with distance with a large N_{D} and a large N_{A}, showing an essentially constant electric field in the first piezoelectric layer. The electric field in the electrode depletion regions decreases with a relatively large magnitude of slope which is proportional to ionized impurity concentration N_{A}.

FIG. 3B shows the variation of electric field with distance with a smaller N_{D} and a smaller N_{A}. The changes in the electrode depletion regions ΔW_{N} and ΔW_{P} with the change in the DC biasing voltage Δ_{VDC1} is greater compared to that for higher doping levels shown in FIG. 3A.

FIG. 4A A schematic cross-sectional view of an IDT1 with embedded electrode doped regions shows qualitatively the variation of the electrode depletion region thicknesses: the electrode depletion region thicknesses decrease towards the central area of the depletion region. The non-uniform electrode depletion region thicknesses may lead to non-uniform mass loadings.

FIG. 4B is a schematic cross-sectional view of an IDT1, showing embedded input electrode doped regions with the same doping type. A bottom electrode layer and a different input DC biasing arrangement is used in this IDT1 for tuning of the frequency.

FIG. 4C is a schematic cross-sectional view of an IDT2, showing embedded output electrode doped regions with the same doping type. A bottom electrode layer and a different output DC biasing voltage arrangement is adopted for tuning of the frequency.

FIG. 5A is a schematic cross-sectional view taken along line A-A′ in the tunable SAW filter (200a) in FIG. 2A or (200b) in FIG. 2B, showing a part of IDT1 having an elevated input positive electrode doped region and an elevated input negative electrode doped region to enhance the mass loading effect.

FIG. 5B is a schematic cross-sectional view taken along line B-B′ in the tunable SAW filter (200a) in FIG. 2A or (200b) in FIG. 2B, showing a part of IDT2 having an elevated output positive electrode doped region and an elevated output negative doped region to enhance the mass loading effect.

FIG. 5C is a schematic cross-sectional view of the tunable SAW input inter digital transducer IDT1 with elevated input electrode doped regions. A first input DC biasing voltage V_{DC1} is applied to create an input positive electrode depletion region and an input negative electrode depletion region, reduce the mass loading associated with the electrode doped neutral regions and increase the frequency of surface acoustic waves to be excited.

FIG. 5D is a schematic cross-sectional view of the tunable SAW output inter digital transducer IDT2 with elevated output electrode doped regions. A first output DC biasing voltage V_{DC1′} is applied to create an output positive electrode depletion region and an output negative electrode depletion region, reduce the mass loading associated with the electrode doped neutral regions and increase the frequency of surface acoustic waves to be detected.

FIG. 5E is a schematic cross-sectional view of the tunable SAW input inter digital transducer IDT1 with elevated input electrode doped regions. A second input DC biasing voltage V_{DC2} is applied to create an increased input positive electrode depletion region and an increased input negative electrode depletion region, reduce further the mass loading associated with the electrode doped neutral regions and increase further the frequency of surface acoustic waves to be excited.

FIG. 5F is a schematic cross-sectional view of the tunable SAW output inter digital transducer IDT2 with elevated output electrode doped regions. A second output DC biasing voltage V_{DC2′} is applied to create an increased output positive electrode depletion region and an increased output negative electrode depletion region, reduce further the mass loading associated with the electrode doped neutral regions and increase further the frequency of surface acoustic waves to be detected.

FIG. 6A is a schematic cross-sectional view of an IDT1, showing elevated input electrode doped regions with the same doping type. A bottom electrode layer and a different input DC biasing arrangement is used in this IDT1 for tuning of frequency.

FIG. 6B is a schematic cross-sectional view of an IDT2, showing elevated input electrode doped regions with the same doping type. A bottom electrode layer and a different output DC biasing arrangement is used in this IDT2 for tuning of frequency.

FIG. 6C is a schematic cross-sectional view of an IDT1, showing elevated electrode doped regions of the same doping type, a bottom electrode layer. A temperature compensation layer is adopted to reduce unwanted change in the frequency of the surface acoustic wave with the variation of temperature.

FIG. 7A is a schematic diagram showing the shift of impedance of an IDT in a tunable SAW filter. As the magnitude of biasing voltage is increased, the resonant frequency increases. Curve 1 is for V_{DC1}, Curve 2 for V_{DC2} and Curve 3 for V_{DC3}.

FIG. 7B shows a schematic diagram showing the shift of transmission characteristics of a tunable SAW filter built using tunable inter digital transducers IDT1 and IDT2 shown in FIG. 2A or FIG. 2B. At a DC biasing voltage of V_{DC1}, the variation of transmission is given as Curve 1 and as the DC biasing voltage is increased to V_{DC2}, the variation of transmission is shifted and is given by Curve 2.

FIG. 8 is a schematic top view showing a tunable input SAW reflector having input electrode pads, input electrode fingers, input electrode doped regions. A DC biasing voltage is applied to control the MR and ML and the frequency of the surface acoustic waves to be reflected.

### DETAILED DESCRIPTION OF THE INVENTION

Two main structures for surface acoustic waves (SAW) inter digital transducers (IDT) and reflectors with tunable and adjustable frequency for SAW devices such as SAW filters are provided according to this invention.

### Tunable SAW Inter Digital Transducers and Filters:

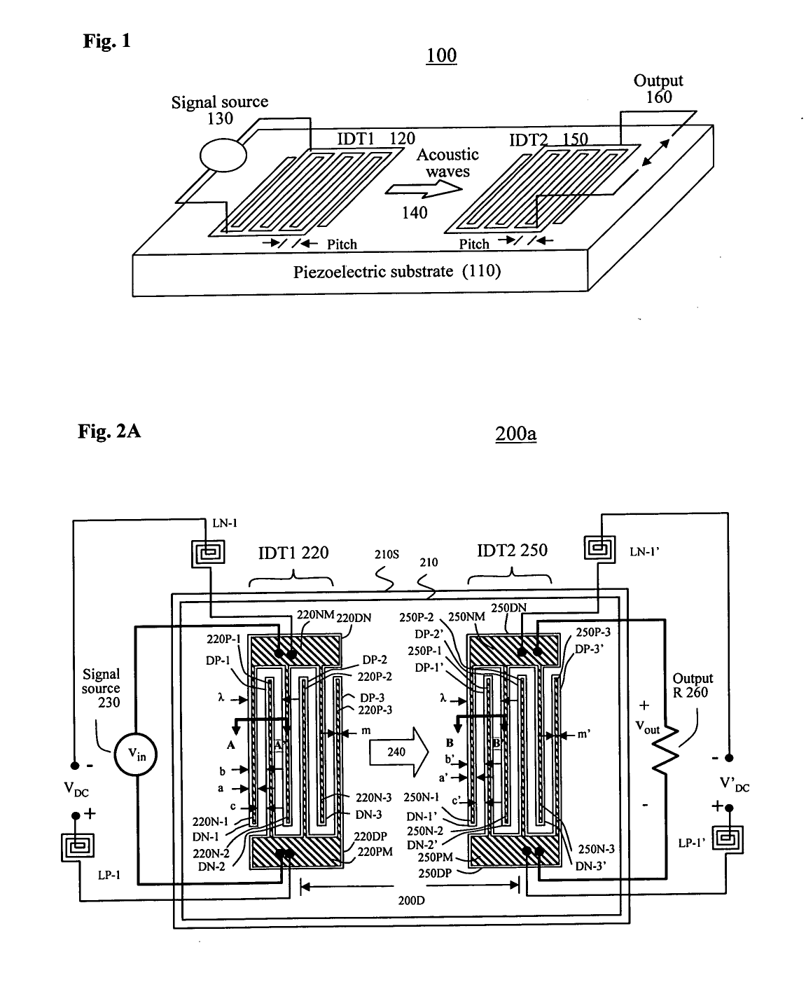

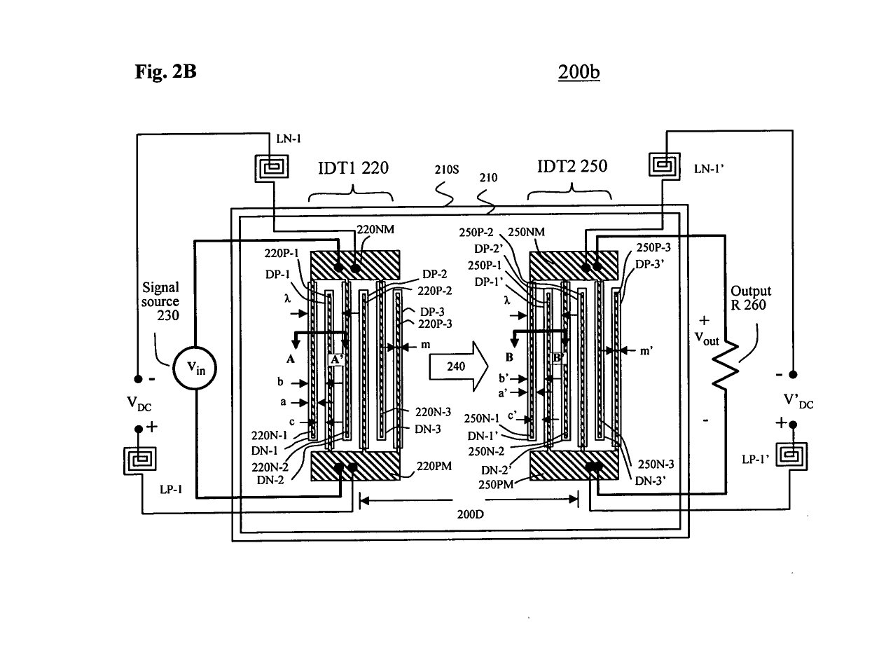

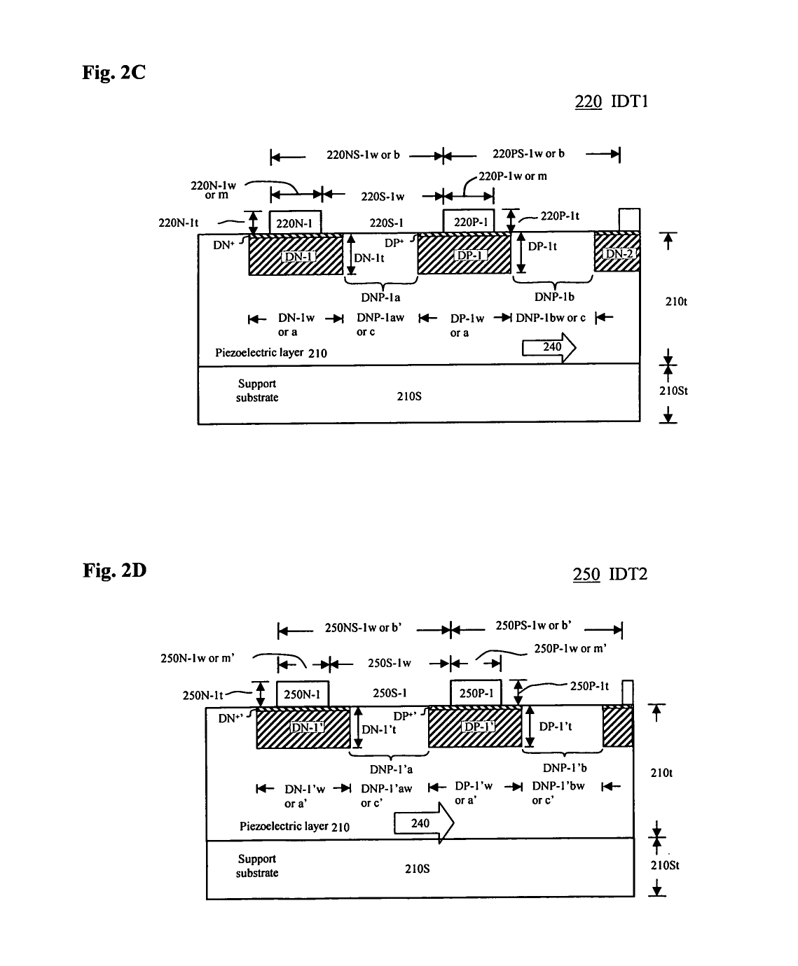

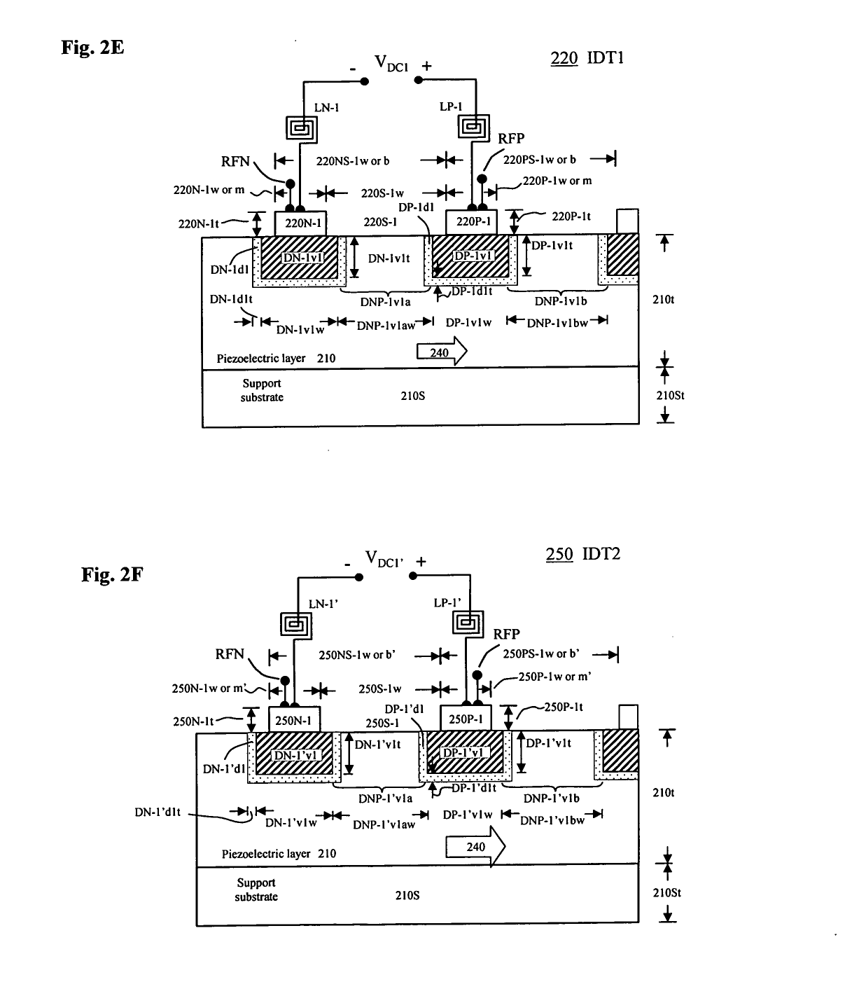

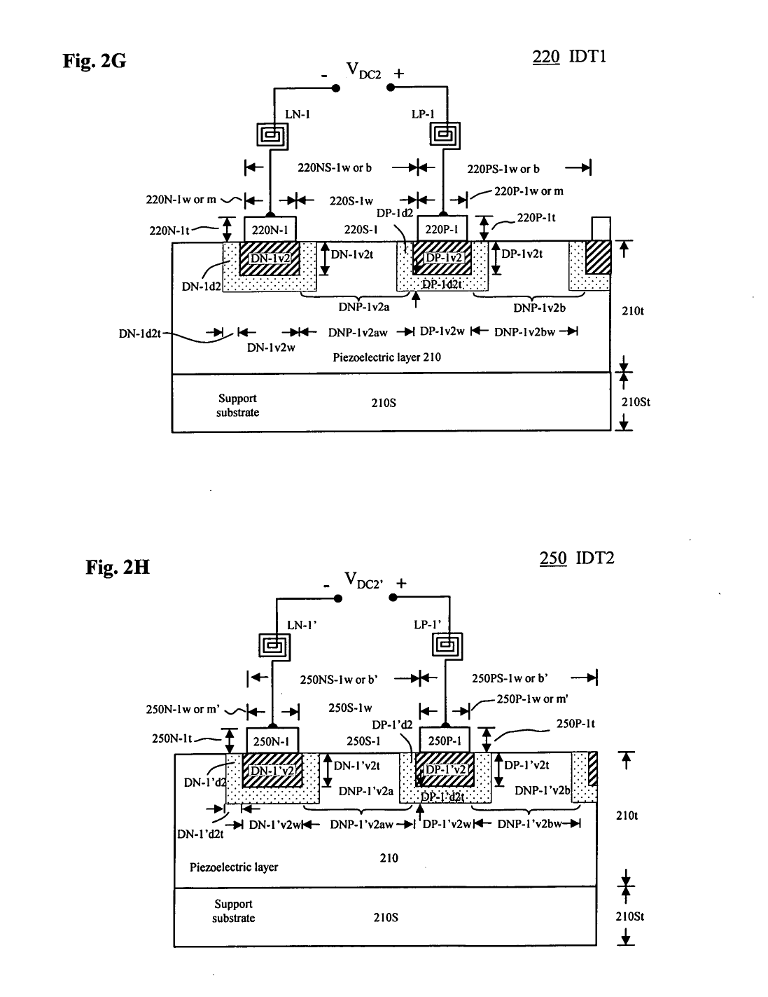

Two main frequency tunable SAW IDTs structures: one with embedded electrode doped regions and the other with elevated electrode doped regions are provided according to this invention and are described using a SAW filter structure shown in FIGS. 2A and 2B. FIG. 2A shows a schematic top view of a surface acoustic wave (SAW) filter (200a) with tunable and adjustable frequency on a first piezoelectric layer (210) which is on a support substrate (210S). The SAW filter (220a) comprises an input inter digital transducer IDT1 (220) having an input positive electrode pad (220PM) on an input positive electrode pad doped region (220DP) connecting with metallic input positive electrode fingers (220P−1, 220P−2, 220P−3) and an input negative electrode pad (220NM) on an input negative electrode pad doped region (220DN) connecting with metallic input negative electrode fingers (220N−1, 220N−2, 220N−3). Each of the input positive electrode fingers (220P−1, 220P−2, 220P−3) sits on one of respective input positive electrode doped regions (DP−1, DP−2, DP−3) and each of the input negative electrode fingers (220N−1, 220N−2, 220N−3) is on one of respective input negative electrode doped regions (DN−1, DN−2, DN−3). The center-to-center distance between adjacent input positive electrode fingers and input negative electrode fingers is controlled to a “pitch or b”. Similarly, the center-to-center distance between adjacent input positive electrode finger doped regions and input negative electrode finger doped regions is also controlled to a “pitch or b”. The input positive electrode doped regions (DP−1, DP−2 and DP−3) are doped piezoelectric semiconductor with an input first doping type (either p-type or n-type) and a doping concentration, while the input negative electrode doped regions (DN−1, DN−2 and DN−3) are also doped piezoelectric semiconductors with an input second doping type (opposite to the input first doping type) and a doping concentration. The input positive electrode pad (220PM) and the input negative electrode pad (220NM) are connected to an electrical signal source Vᵢₙ (230) to excite surface acoustic waves (240) at a frequency f≈v/(2×b), with v being the velocity of the surface acoustic waves (240).

The SAW filter (220a) also comprises an output inter digital transducer IDT2 (250) having an output positive electrode pad (250PM) on an output positive electrode pad doped region (250DP) connecting with metallic output positive electrode fingers (250P−1, 250P−2, 250P−3) and an output negative electrode pad (250NM) on an output negative electrode pad doped region (250DN) connecting with metallic output negative electrode fingers (250N−1, 250N−2, 250N−3). Each of the output positive electrode fingers (250P−1, 250P−2, 250P−3) sits on one of respective output positive electrode doped regions (DP−1′, DP−2′, DP−3′) and each of the output negative electrode fingers (250N−1, 250N−2, 250N−3) is on one of respective output negative electrode doped regions (DN−1′, DN−2′, DN−3′). The center-to-center distance between adjacent output positive electrode fingers and output negative electrode fingers is controlled to a pitch or b′. Similarly, the center-to-center distance between adjacent output positive electrode forgers doped regions and output negative electrode finger doped regions is also controlled to the pitch or b′. Here, the pitch b′ is selected to be equal to the pitch b of the input inter digital transducer (220). The output positive electrode doped regions (DP−1′, DP−2′ and DP−3′) are doped piezoelectric semiconductor with an output first doping type (either p-type or n-type) and a doping concentration, while the output negative electrode doped regions (DN−1′, DN−2′ and DN−3′) are also doped piezoelectric semiconductors with an output second doping type (opposite to the output first doping type) and a doping concentration. The output positive electrode pad (250PM) and the output negative electrode pad (250NM) are connected to an output resistor R (260) to receive the surface acoustic waves (240) and covert them into an output electrical signal Vₒᵤₜ across an output resistor R (260).

The input inter digital transducer (220) and output inter digital transducer (250) are kept apart by an IDT center-to-center distance (200D). The input electrode doped region width “a” is kept to be substantially equal to half of the pitch “b” so that the spacing between adjacent input electrode doped regions “c” is also substantially equal to half of the pitch “b”. Whereas the output electrode doped region width “a′” is kept to be substantially equal to half of the pitch “b′” (b′=b) and also equal to the input electrode doped region width “a” so that spacing between adjacent output electrode doped regions “c′” is also substantially equal to half of the pitch (b′=b). The input electrode finger width “m” is selected to be the same as the output electrode finger width “m′” and both “m” and “m′” is no more than electrode doped region widths “a” and “a′”.

An input DC biasing voltage V_{DC} is connected to the input inter digital transducer IDT1 (220) through blocking inductors (LN−1) and (LP−1) to tune and adjust the frequency of the surface acoustic waves to be excited by IDT1. An output DC biasing voltage V′_{DC} is connected to the output inter digital transducer IDT2 (250) through blocking inductors (LN−1′) and (LP−1′) to tune and adjust frequency of the surface acoustic waves to be received or detected by IDT2. Value of the input DC biasing voltage V_{DC} is preferably selected to be the same as that of the output DC biasing voltage V′_{DC} to achieve synchronous tuning and adjustment of the frequencies. The value of pitch “b” is selected during design and fabrication of the SAW devices and the wavelength of surface acoustic waves to be excited and to propagate is given by: λ=2b. Therefore, according to this invention, the frequency of the surface acoustic waves to be excited by the SAW input inter digital transducer IDT1 is first specified by the design and the fabrication and is adjustable by the DC biasing voltages V_{DC}. Similarly, the frequency of surface acoustic waves to be detected or received by the output inter digital transducer IDT2 is also determined by the design and the fabrication and is adjustable by the DC biasing voltage V′_{DC}. The value of λ together with the velocity v of the surface acoustic waves (240) thus determine a unique central frequency f=v/λ of the excitation, propagating and detection of the surface acoustic waves.

According to this invention, Material of the first piezoelectric layer (210) is selected from a material group of piezoelectric materials including: LiNbO₃, LiTaO₃, ZnO, AlN, GaN, AlGaN, LiTaO₃, GaAs, AlGaAs and etc. Take one of the well developed piezoelectric substrates LiNbO₃ as an example, the velocity of acoustic waves v is about 4,000 m/sec. To obtain a filter with a central frequency f₀=2 GHz, the wavelength of the acoustic wave is λ=(4000 m/sec)/(2×10⁹/sec)=2×10⁻⁴ cm. The value of pitch (b, b′) in the above figure is then equal to 1 μm. Assuming that the width of electrode doped regions (a, a′) and space between adjacent electrode doped regions (c, c′) are equal, then the electrode doped region width is 0.5 μm. To fabricate IDTs for SAWs at higher frequencies, more advanced lithography tools and more severe processing control will be needed.

The support substrate are selected from a material group: LiNbO₃, LiTaO₃, PZT, AlN, GaN, AlGaN, ZnO, GaAs, AlAs, AlGaAs, Al₂O₃, BaTiO₃, quartz, KNbO₃, Si, sapphire, quartz, glass and plastic. Thickness of the support substrate (210St) is selected by considering the mechanical strength, thermal dissipation and acoustic properties requirements. When the material of the first piezoelectric layer (210) is selected to be the same as the support substrate (210S), they can be combined into a single piezoelectric substrate.

Materials for the input positive electrode doped region (DP−1, DP−2, DP−3) and the input negative electrode doped region (DN−1, DN−2, DN−3) are selected from a group of piezoelectric semiconductors including: AlN, GaN, AlGaN, ZnO, GaAs, AlAs, AlGaAs as long as they are piezoelectric with sufficient acoustic coupling coefficients, are semiconducting and can be doped to n-type and/or p-type conductions.

Materials for the input positive electrode fingers (220P−1, 220P−2, 220P−3), input negative electrode fingers (220N−1, 220N−2, 220N−3), the input positive electrode pad (220PM) and the input negative electrode pad (220NM) are selected from a metal group of: Ti, Al, W, Pt, Mo, Cr, Pd, Ta, Cu, Cr, Au, Ni, Ag, Ru, Ir and other metals and their combinations. Materials for the output positive electrode fingers (250P−1, 250P−2, 250P−3), input negative electrode fingers (250N−1, 250N−2, 250N−3), the input positive electrode pad (250PM) and the input negative electrode pad (250NM) are selected from the same group of metals and metal alloys so that they can provide the same electrical performance and can be deposited in the same deposition run.

In addition, there are periodic metal grids deposited to the left of input inter digital electrode IDT1 (220) and to the right of the output inter digital electrode IDT2 (250) to serve as reflectors and to reduce unwanted loss of surface acoustic wave energy. These periodic metal grids are not shown in FIGS. 2A and 2B for simplicity reasons and the reflectors will be described separately in FIG. 8. Although only three pairs of electrode fingers are shown for IDT1 (220) and IDT2 (250) in FIG. 2A and FIG. 2B, it is understood that in practical SAW devices, the number of electrode fingers is often large in order to achieve the required performance. The frequency tuning and adjustment for the surface acoustic waves in the SAW device involving IDT1 and IDT2 is achieved by controlling and adjusting the magnitude and polarity of the DC biasing voltages V_{DC} and V′_{DC} according to this invention.

It is noted that the effects of tuning and adjustment of frequency for the SAW structure (200a) shown in FIG. 2A may well be implemented using another SAW structure (200b) shown in FIG. 2B. FIG. 2B shows a schematic top view of the tunable and adjustable SAW filter (200b) having an input inter digital transducer IDT1 (220) and an output inter digital transducer IDT2 (250) on a first piezoelectric layer (210) which is on a support substrate (210S). The SAW filter (200b) comprises an input negative electrode pad (220NM), an input positive electrode pad (220PM), an output negative electrode pad (250NM) and an output positive electrode pad (250PM) which are directly deposited on the first piezoelectric layer (210). Other elements and components in FIG. 2B are the same as those in FIG. 2A with the absence of (220DP, 220DN) and (250DP, 250DN in FIG. 2A). Although only three pairs of electrode fingers are shown for IDT1 and IDT2 in FIG. 2B, it is understood that in practical SAW devices, the number of electrode fingers is often large in order to achieve the required performance.

An input DC biasing voltage V_{DC} is connected to the input inter digital transducer IDT1 (220) through blocking inductors (LN−1) and (LP−1) to tune and adjust the frequency of the surface acoustic waves to be excited by IDT1. An output biasing voltage V′_{DC} is connected to the output inter digital transducer IDT2 (250) through blocking inductors (LN−1′) and (LP−1′) to tune and adjust frequency of the surface acoustic waves to be received or detected by IDT2. Value of V_{DC} is preferably selected to be the same as that of V′_{DC} to achieve synchronous tuning and adjustment for the frequencies. Same as (200a) in FIG. 2B, there are periodic metal grids deposited to the left of input inter digital electrode IDT1 and to the right of the output inter digital electrode IDT2 in (200b) to serve as reflectors and to reduce unwanted loss of surface acoustic wave energy. These periodic metal grids are not shown in FIG. 2B for simplicity reasons and will be given in FIG. 8. The tuning and adjustment of frequency for the surface acoustic waves in this SAW device involving IDT1 and IDT2 is achieved by controlling and adjusting the magnitude and polarity of the DC biasing voltages V_{DC} and V′_{DC} according to this invention.

IDTs with Embedded Electrode Doped Regions:

A schematic cross-sectional view of a tunable and adjustable IDT1 with embedded input electrode doped regions, taken along line A-A′ in the tunable and adjustable SAW filter (200a) in FIG. 2A or (200b) in FIG. 2B is shown in FIG. 2C. It shows a part of the IDT1 (220) on a first piezoelectric layer (210) with a first piezoelectric layer thickness (210t) which is on a support substrate (210S) having a support substrate thickness (210St). An input positive electrode doped region (DP−1) with an input first doping type (could be either p-type or n-type) and a doping concentration (N_{D} for n-type or N_{A} for p-type) is embedded in the first piezoelectric layer (210). This input positive electrode doped region (DP−1) having an input positive electrode doped region width (DP−1w or a) and an input positive electrode doped region thickness (DP−1t) is created in the first piezoelectric layer (210) by impurity diffusion or doping such as ion implantation and annealing. An input positive electrode finger (220P−1) with an input positive electrode finger width (220P−1w or m) and an input positive electrode finger thickness (220P−1t) is deposited on top of and is aligned to the input positive electrode doped region (DP−1). An input negative electrode doped region (DN−1) with an input second doping type (opposite to the input first doping type) and a doping concentration (N_{D} for n-type or N_{A} for p-type) is embedded in the first piezoelectric layer (210). This input negative electrode doped region (DN−1) has an input negative electrode doped region width (DN−1w or a) and an input negative electrode doped region thickness (DN−1t) and it is created in the first piezoelectric layer (210) by impurity diffusion or doping. An input negative electrode finger (220N−1) with an input negative electrode finger width (220N−1w or m) and an input negative electrode finger thickness (220N−1t) is deposited on top of and is aligned to the input negative electrode doped region (DN−1).

The space between the input positive electrode finger (220P−1) and the input negative electrode finger (220N−1) defines an input electrode spacing region (220S−1) with an input electrode spacing region width (220S−1w). The pitch (220NS−1w or b) is equal to the sum of the input negative electrode finger width (220N−1w or m) and the input electrode spacing region width (220S−1w) and it is also equal to (220PS−1w). The space between an input positive electrode doped region and an adjacent input negative electrode doped region defines an input electrode doped region spacing (DNP−1a or DNP−1b) having an input electrode doped region spacing width (DNP−1aw or DNP−1bw or c). Wavelength λ of the surface acoustic waves (240) to be excited is substantially equal to two times of the pitch value: 2×(220NS−1w)=2×(220PS−1w)=2b. Hence, frequency of the surface acoustic waves to be excited is given by: f=v/2b, here v is the velocity of the surface acoustic waves in the first piezoelectric layer (210) under the electrodes associated with the input inter digital transducer IDT1.

It should be noted that the above described frequency is obtained under ideal conditions where the mass of input positive and negative electrode fingers is equal to zero and the mass of the input positive and negative electrode doped regions is also equal to zero. Under the ideal conditions, the mass loading effects of the input positive and output negative electrode fingers and of the input electrode doped regions are negligible. More description on the mass loading effect will be provided later.

Materials for the support substrate (210S) are selected from a material group of: LiNbO₃, LiTaO₃, PZT, AlN, GaN, AlGaN, ZnO, GaAs, AlAs, AlGaAs, Al₂O₃, BaTiO₃, quartz, KNbO₃, Si, sapphire, quartz, glass and plastic. Thickness of the support substrate (210St) is selected by considering the mechanical strength, thermal dissipation and acoustic properties requirements. Materials for the first piezoelectric layer (210) are selected from a material group including: LiNbO₃, LiTaO3, PZT, AlN, GaN, AlGaN, ZnO, GaAs, AlAs, AlGaAs, BaTiO₃, quartz and KNbO₃, as long as they are piezoelectric materials with a sufficient coupling coefficient. When the material of the first piezoelectric layer (210) is selected to be the same as the support substrate (210S), they can be combined into a single piezoelectric substrate. Materials of the input positive electrode doped region (DP−1) and of the input negative electrode doped region (DN−1) are selected from a group of piezoelectric semiconductors including: AlN, GaN, AlGaN, ZnO, GaAs, AlAs, AlGaAs as long as they are piezoelectric with sufficient acoustic coupling coefficients, are semiconducting and can be doped to n-type and/or p-type conductions.

It is preferable to have ohmic contacts between the input positive electrode fingers (220P−1, 220P−2, 220P−3) (refer to FIG. 2A) and the input positive electrode doped regions (DP−1, DP−2, DP−3) and between the input negative electrode fingers (220N−1, 220N−2, 220N−3) and the input negative electrode doped regions (DN−1, DN−2, DN−3). Hence, when the input positive electrode doped region is doped to have a p-type conduction, the first layer of the input positive electrode fingers should have a work function larger than electron affinity of the piezoelectric semiconducting material of the input positive electrode doped regions. Opposite will be true when the doping type is opposite. Since the input second doping type is opposite to the first doping type, the negative electrode doped region is doped to an n-type conduction. Therefore, the first layer of the input negative electrode fingers should have a work function close to or less than electron affinity of the piezoelectric semiconducting material of the input negative electrode doped regions. Materials for the input positive electrode fingers, input negative electrode fingers are selected from a metal group of: Ti, Al, W, Pt, Mo, Cr, Pd, Ta, Cu, Cr, Au, Ni, Ag, Ru, Ir and other metals and their combinations. Furthermore, metals for forming the input positive electrode fingers and the input negative electrode fingers are preferably selected to be the same so that they can provide the same electrical performance and can be deposited in the same deposition run.

According one embodiment of this invention, the input positive electrode finger thickness (220P−1t) and the input negative electrode finger thickness (220N−1t) are preferably selected to be in a range of 10 to 400 nm and is more preferably selected to be in a range of 20 to 300 nm, depending on the operation frequency and the frequency tuning range required.

In order to facilitate ohmic contacts, it is preferable to have a heavily doped surface layer on the input positive electrode doped regions (DP−1, DP−2, DP−3) and the input negative electrode doped regions (DN−1, DN−2, DN−3). FIG. 2C shows a heavily n⁺-doped DN⁺ layer on the n-type input negative electrode doped region (DN−1) and a heavily p⁺-doped DP⁺ layer on the p-type input positive electrode doped region (DP−1). Thicknesses of the DN⁺ layer and the DP⁺ layer should be kept small (preferably in the order of 20 nm or less).

In order to decrease the mass loading effect of the input positive electrode fingers and input negative electrode fingers and to increase the frequency tuning sensitivities, it is preferred to select metal materials with smaller atomic weights such as Al, Ti as a part of the input electrode fingers. It is also preferable to have a reduced input electrode finger thickness (in a range of 20 to 200 nm). Furthermore, a multilayer metal structure involving at least two metal materials may be advantageously adopted to improve the adhesion of the input positive electrode fingers and the input negative electrode fingers and to reduce the contact resistance.

In the depletion regions of a doped piezoelectric semiconductor (such as the input positive/negative electrode doped regions) and in the un-doped first piezoelectric layer, the charge carrier density is small (below 10¹⁰ cm⁻³) and the electrical conductivity is very low (˜10⁻¹⁰/ohm-cm or less) so that the depletion region and the un-doped first piezoelectric layer behave as an insulator. In the neutral regions of the input positive/negative electrode doped regions, the charge carrier density is large (preferably in the range of 10¹⁴ to 10²¹ cm³ and is more preferably in the range of 10¹⁵ to 10²⁰ cm⁻³, dependent on the operation frequency and tuning range required) so the electrical conductivity is large and the neutral regions of the input positive/negative electrode doped regions behave as a conductor. In the heavily doped layers DP⁺ and DN⁺, the charge carrier density is preferably to be more than 10²⁰ cm⁻³.

According to one other embodiment of this invention, the input positive electrode doped region thickness (DP−1t) and the input negative electrode doped region thickness (DN−1t) are preferably selected to be in a range of 10 to 2000 nm and more preferably in a range of 20 to 1000 nm, dependent on the operation frequency and the tuning range required. The selection of the positive electrode doped region thickness (DP−1t) and the negative electrode doped region thickness (DN−1t) are thus determined by the frequency of the surface acoustic waves, tuning and adjustment range of the frequency and sensitivity of the tuning required.

The structure of the output inter digital transducer IDT2 (250) is similar to that of the input inter digital transducer IDT1 (220). FIG. 2D shows a schematic cross-sectional view of the tunable and adjustable SAW filter (200a or 200b in FIGS. 2A and 2B), taking along line B-B′. It shows a portion of the output inter digital transducer IDT2 (250) on a first piezoelectric layer (210) with a first piezoelectric layer thickness (210t) which is on a support substrate (210S) with a support substrate thickness (210St).

An output positive electrode doped region (DP−1′) with an output first doping type (either n or p) and a doping concentration (N_{D} for n-type or N_{A} for p-type) is embedded in the first piezoelectric layer (210). The output positive electrode doped region (DP−1′) having an output positive electrode doped region width (DP−1′w or a′) and an output positive electrode doped region thickness (DP−1′t) is created in the first piezoelectric layer (210) by impurity diffusion or doping. An output positive electrode finger (250P−1) with an output positive electrode finger width (250P−1w or m′) and an output positive electrode finger thickness (250P−1t) is deposited on top of and is aligned to the output positive electrode doped region (DP−1′). An output negative electrode doped region (DN−1′) with an output second doping type (opposite to the output first doping type) and a doping concentration (N_{D} for n-type or N_{A} for p-type) is embedded in the first piezoelectric layer (210). The output negative electrode doped region (DN−1′) having an output negative electrode doped region width (DN−1′w or a′) and an output negative electrode doped region thickness (DN−1′t) is created in the first piezoelectric layer (210) by impurity diffusion or doping. An output negative electrode finger (250N−1) with an output negative electrode finger width (250N−1w or m′) and an output negative electrode finger thickness (250N−1t) is deposited on top of and aligned to the output negative electrode doped region (DN−1′).

The space between the output positive electrode finger (250P−1) and the output negative electrode finger (250N−1) defines an output electrode spacing region (250S−1) with an output electrode spacing region width (250S−1w). The pitch (250NS−1w or b′) is equal to the sum of the output negative electrode finger width (250N−1w) and the output electrode spacing region width (250S−1w) and is also equal to (250PS−1w). The space between an output positive electrode doped region and an adjacent output negative electrode doped region defines an output electrode doped region spacing (DNP−1′a or DNP−1′b) having an output electrode doped region spacing width (DNP−1′aw or DNP−1′bw or c′). Wavelength X of surface acoustic waves to be detected or received is substantially equal to two times of the pitch value: 2×(250NS−1w)=2×(250PS−1w)=2b′. Hence, the frequency of the acoustic wave is given by: f=v/λ=v/2b′, here v is the velocity of surface acoustic waves in the first piezoelectric layer (210).

It should be noted that the above described frequency is obtained under ideal conditions where the mass of output positive and negative electrode fingers and the mass of the output positive and negative electrode doped regions are zero. Under the ideal conditions, the mass loading effects of the output positive and output negative electrode fingers and of the output electrode doped regions are negligible.

Materials of the output positive electrode doped region (DP−1′) and the output negative electrode doped region (DN−1′) are selected from a group of piezoelectric semiconductors including: AlN, GaN, AlGaN, ZnO, GaAs, AlAs, AlGaAs as long as they are piezoelectric with a sufficient acoustic coupling coefficient and semiconducting and can be doped to n-type and/or p-type conduction.

It is preferable to have ohmic contacts between the output positive electrode fingers (250P−1, 250P−2, 250P−3, FIGS. 2A and 2B) and the output positive electrode doped regions (DP−1′, DP−2′, DP−3′) and between output negative electrode fingers (250N−1, 250N−2, 250N−3) and the output negative electrode doped regions (DP−1′, DP−2′, DP−3′). Hence, when the output positive electrode doped region is doped to have a p-type conduction, the first layer of the output positive electrode fingers should have a work function larger than electron affinity of piezoelectric semiconducting material of the output positive electrode doped regions. When the output first doping type is p-type, the output negative electrode doped region is doped to an n-type conduction. Therefore, the first layer of output negative electrode fingers should have a work function close to or less than electron affinity of piezoelectric semiconducting material of the output negative electrode doped regions.

Materials for the output positive electrode fingers and the output negative electrode fingers are selected from a group of: Ti, Al, W, Pt, Mo, Cr, Pd, Ta, Cu, Cr, Au, Ni, Ag, Ru, Ir and other metals and their combinations. Furthermore, metals for forming the output positive electrode fingers and the output negative electrode fingers are preferably selected to be the same so that they can provide the same electrical performance and can be deposited in the same deposition run. In order to decrease the mass loading effect of the output positive electrode fingers and the output negative electrode fingers and to increase the frequency tuning sensitivities, it is preferred to select metal materials with smaller atomic weights such as Al, Ti as a part of the output electrode fingers. It is also preferable to have a reduced output electrode finger thickness (e.g. in a range of 20 to 200 nm). Furthermore, a multilayer metal structure involving at least two metal materials may be advantageously adopted to improve the adhesion of the output positive electrode fingers and the output negative electrode fingers and to reduce the contact resistance.

According to one embodiment of this invention, the output positive electrode finger thickness (250P−1t) and the output negative electrode finger thickness (250N−1t) are preferably selected to be in a range of 10 to 400 nm and is more preferably selected to be in a range of 20 to 300 nm, dependent on the operation frequency and the frequency tuning range required.

In order to facilitate ohmic contacts, it is preferable to have a heavily doped surface layer on the output positive electrode doped regions (DP−1′, DP−2′, DP−3′) and the output negative electrode doped regions (DN−1′, DN−2′, DN−3′). FIG. 2D shows a heavily n⁺-doped DN⁺′ layer on the n-type output negative electrode doped region (DN−1′) and a heavily p⁺-doped DP⁺′ layer on the p-type output positive electrode doped region (DP−1′). Thicknesses of the DN⁺′ layer and the DP⁺′ layer should be kept small (in the order of 20 nm or less). For simplicity reasons, in subsequent drawings (FIGS. 2E˜2I), the heavily doped layers DP⁺, DN⁺, (or DP⁺′ and DN⁺′) will not be shown.

In the depletion regions of a doped piezoelectric semiconductor (such as the output positive/negative electrode doped regions) and in the un-doped first piezoelectric layer, the charge carrier density is usually small (below 10¹⁰ cm⁻³) and the electrical conductivity is very low (˜10⁻¹⁰/ohm-cm or less), so that the depletion region and the un-doped first piezoelectric layer behave as insulators. In the neutral regions of the input positive/negative electrode doped regions, the charge carrier density is large (preferably in the range of 10¹⁴ to 10²¹ cm⁻³ and is more preferably in the range of 10¹⁵ to 10²⁰ cm⁻³, depending on the operation frequency and tuning range required) and the electrical conductivity is high and the neutral regions behave as conductors. In the heavily doped DP⁺′ and DN⁺′ layers, the carrier concentration is preferably more than 10²⁰ cm⁻³.

According to one other embodiment of this invention, the output positive electrode doped region thickness (DP−1′t) and the output negative electrode doped region thickness (DN−1′t) are preferably selected to be in a range of 10 to 2000 nm and more preferably in a range of 20 to 1000 nm, depending on the operation frequency and the tuning range required. The selection of the positive electrode doped region thickness (DP−1′t) and the negative electrode doped region thickness (DN−1′t) are thus determined by the frequency of surface acoustic waves, tuning and adjustment range of the frequency, and sensitivity of the tuning required.

### Mass Loading Effect and Metallization Ratio:

In an non-ideal input inter digital transducer IDT1, the mass of the input positive/negative electrodes and the input electrode doped regions has non zero values and a mass loading (ML) effect has to be considered. Similarly, in a non-ideal output inter digital transducer IDT2, the mass of the output positive/negative electrodes and the output electrode doped regions has finite values and a mass loading (ML) effect has to be considered. When the mass of input positive and negative electrodes and doped regions of the IDT1 shown in FIG. 2C is finite, there is also a finite mass loading effect. This mass loading effect will lower the frequency f₁ from an ideal frequency fᵢ for the surface acoustic waves to be excited or to be received, so that there is a mass loading frequency difference given by: Δf_{ML}=fᵢ−f₁. Here, fᵢ is the ideal frequency devoid of any mass loading effects.

In addition to the mass loading effect, there is a metallization ratio effect. Metallization ratio (MR) in IDT1 is defined as the ratio between the input positive or negative electrode doped region width (DP−1w or DN−1w or a) to the pitch value (220PS−1w or 220NS−1w or b): Metallization ratio in IDT2 is defined as the ratio between the output positive or negative electrode doped region width (DP−1′w or DN−1′w or a′) to the pitch value (250PS−1w or 250NS−1w or b′): a′/b′. When the metallization ratio (a/b, a′/b′) is small, the effects on the surface acoustic wave propagation are small and the velocity of the surface acoustic waves is large and the frequency of the surface acoustic waves is high. When the metallization ratio is increased, the effects of the MR on the surface acoustic wave propagation increase and the velocity of the surface acoustic waves decreases so that the frequency f decreases as the wavelength λ is constant. The frequency difference due to metallization ratio difference or the metallization ratio frequency difference is given by Δf_{MR}.

Since an increase in both mass loading and a metallization ratio will lead to a decrease in the resonant frequency f₁ of the IDTs (or the frequency of acoustic waves to be excited or detected), a basic frequency f₀ may be defined as the lowest resonant frequency in the tunable IDTs, which is the frequency when both the mass loading and the metallization ratio are at maximum values. Therefore, the mass loading frequency difference Δf_{ML}(Δf_{ML}=f₁−f₀, which cause an increase in frequency from f₀), increases with the decrease in masses of the positive/negative electrodes and the electrode doped regions in an IDT. Similarly, when the masses of the positive/negative electrodes and the electrode doped regions of the IDTs shown in FIGS. 2C and 2D is finite, there is a finite mass loading effect. Since f₀ is defined as the lowest frequency in the tunable IDTs, the mass loading frequency difference Δf_{ML} and the metallization ratio frequency difference Δf_{MR} are positive according this invention.

In an IDT without a depletion layer formed in the electrode doped regions (such as the ones shown in FIGS. 2C and 2D), the entire electrode doped regions act as conductors and the mass loading is at its maximum value. For the input inter digital transducer IDT1, f₀ is the basic frequency of the surface acoustic waves to be excited with both the metallization ratio and the mass loading at a maximum value: i.e. when there is no depletion layers formed in the input positive and negative electrode doped regions. Whereas for the IDT2, f₀ is the basic frequency of the surface acoustic waves to be detected by IDT2 with both the metallization ratio and the mass loading at a maximum value: i.e. when there is no depletion layers formed in the output positive and negative electrode doped regions.

According to this invention, when the mass loading frequency difference for the input IDT1 is controlled to be same as the mass loading frequency difference for the output IDT2, the frequency of transmission of a SAW device such as a SAW filter formed may be tuned and adjusted by adjusting the mass loading (preferably by electrical means). Hence, at a given DC biasing voltage V_{DC1}, frequency f₁ of the surface acoustic waves is approximately equal to: f₁=f₀+Δf_{MR1}+Δf_{ML1}, here f₀ is the basic frequency when the mass loading and the metallization ratio are at their maximum values. At another DC biasing voltage V_{DC2}, frequency f₂ of the surface acoustic waves is equal to: f₂=f₀+Δf_{MR2}+Δf_{ML2}.

According to this invention, the adjustment and control of the neutral region width of the positive and negative electrode doped regions by a DC biasing voltage is used to adjust and control metallization ratio of an IDT whereas the adjustment and control of the neutral layer thickness of the positive and negative electrode doped regions by a DC biasing voltage is used to adjust and control the mass loading in the present SAW transducers for SAW filters, oscillators, switches and duplexers, hence to achieve frequency tuning and adjustment by applying and varying DC biasing voltage to the IDTs.

When a DC biasing voltage is applied to an IDT, a depletion layer forms in the positive or negative electrode doped regions which causes a decrease in the size (width and thickness) of the positive and negative doped region neutral layers (which is also called positive and negative electrode doped neutral regions for simplicity). As the positive electrode doped neutral region and the negative electrode doped neutral region are neutral piezoelectric semiconductors which are electrically conducting, when an input RF signal source is applied across the positive electrode fingers and the negative electrode fingers, electric fields due to the input RF signals do not occur in these conducting negative electrode doped neutral regions and the positive electrode doped neutral regions. Therefore, when a DC biasing voltage is applied to an IDT, the reduced positive electrode doped neutral regions forms a part of reduced loading mass with the positive electrode finger and the reduced negative electrode doped neutral region forms another part of reduced loading mass with the negative electrode finger, so that a shift in the frequency of surface acoustic waves to be excited or to be received from the basic frequency f₀ is effected. The amount of frequency difference or frequency shift due to the reduced loading mass is determined by the total reduced mass of the negative electrode finger and the negative electrode doped neutral region (per unit area) and the total reduced mass of the positive electrode finger and the positive electrode doped neutral region (per unit area).

The embodiments of this invention thus take advantage of the above-described mass loading effect and provide SAW structures where the mass associated with the positive electrode doped neutral region and mass associated with the negative electrode doped neutral region are tuned or adjusted by a DC biasing voltage applied. In addition, the present invention also takes advantage of a metallization ratio effect on the shift of frequency.

The effects of a DC biasing voltage applied on the tuning and adjustment of frequency in SAW IDTs and devices will be described in more details using FIGS. 2E-2H.

FIG. 2E shows the same schematic cross-sectional view of the tunable and adjustable SAW filter (200a) shown in FIG. 2C, except a first input DC biasing voltage V_{DC1} is applied between the input positive electrode finger (220P−1) through an input positive electrode pad (220PM, FIG. 2A) and an input positive blocking inductor (LP1), and the input negative electrode finger (220N−1) through the input negative electrode pad (220NM, FIG. 2A) and an input negative blocking inductor (LN1). The positive and negative blocking inductors (LP1 and LN1) are adopted to prevent leakage of RF signal to the input positive electrode finger (220P−1) and the input negative electrode finger (220N−1). The RF signal is applied through a positive RF contact (RFP) and a negative RF contact (RFN). The first input DC biasing voltage V_{DC1} is applied to create and control an input positive electrode depletion region (DP−1d1) with an input positive electrode depletion region thickness (DP−1d1t) and to create and control an input negative electrode depletion region (DN−1d1) with an input negative electrode depletion region thickness (DN−1d1t). The input negative electrode depletion region thickness (DN−1d1t) is substantially the same in magnitude as the input positive electrode depletion region thickness (DP−1d1t). It should be noted that due to the formation of the input positive and negative electrode depletion regions (DP−1d1, DN−1d1), the input electrode doped region spacing widths or the first piezoelectric layer width (DNP−1v1aw or DNP−1v1bw) between the input positive electrode doped neutral region (DP−1v1) and the input negative electrode doped neutral region (DN−1v1) is increased from (DNP−1aw or DNP−1bw) in FIG. 2C.

The creation of the input negative electrode depletion region (DN−1d1), the input positive electrode depletion region (DP−1d1) and the thickness of them (DN−1d1t, DP−1d1t) are controlled by the polarity and the magnitude of the first input DC biasing voltage V_{DC1}. Here V_{DC1} could be a positive or negative in polarity but with a small magnitude. The application of the V_{DC1} and the creation of the depletion regions (DP−1d1 and DN−1d1) result in an input negative electrode doped neutral region thickness and an input negative electrode doped neutral region width (DN−1v1t and DN−1v1w) and an input positive electrode doped neutral region thickness and width (DP−1v1t, DP−1v1w). The thicknesses and widths of the input positive and negative doped neutral regions (DP−1v1t and DN−1v1t, DP−1v1w and DN−1v1w) are smaller than the input electrode doped region thicknesses and widths (DP−1t and DN−1t, DP−1w and DN−1w, in FIG. 2C). Therefore, the mass of loading associated with the input positive electrode finger (220P−1) which is the sum of mass of the input positive electrode doped neutral region (DP−1v1) and mass of the input positive electrode finger (220P−1) will decrease. Whereas the mass of loading associated with the input negative electrode finger (220N−1) which is equal to the sum of mass of the input negative electrode doped neutral region (DN−1v1) and mass of the input negative electrode finger (220N−1) also deceases simultaneously due to the formation of the input negative electrode depletion region (DN−1d1). The decrease in mass of loading will cause an increase in the velocity of the surface acoustic waves (240) which will increase the frequency of the surface acoustic waves from the basic frequency f₀ to a new value f₁. Here, f₀ is the frequency when there is no input positive and negative electrode depletion regions. Hence, when the total mass of input positive and negative electrode fingers and electrode doped neutral regions is decreased, there is a decrease in the mass loading effect and hence a mass loading frequency difference Δf_{ML1}=f₁−f₀.

As mentioned before, the metallization ratio will affect the frequency as well. Metallization ratio is defined as the ratio between the input positive (or the negative) electrode doped region width to the pitch value. In FIG. 2E, MR=(DP−1v1w)/(220PS−1w)=(DP−1v1w)/b (or (DN−1v1w)/(220NS−1w)=(DN−1v1w)/b) is reduced from the MR value in FIG. 2C. With a fixed ML, when the MR is decreased, the effects on the surface acoustic wave propagation decreases and the velocity v of the surface acoustic waves increases: the frequency of the surface acoustic waves increases. The frequency difference due to metallization ratio or metallization ratio frequency difference is given by Δf_{MR}. Due to the formation of the input positive and negative electrode doped depletion regions with the application of V_{DC1}, MR decreases and the frequency of the surface acoustic waves increases.

According to this invention, the adjustment and control of the input positive electrode doped neutral region width (DP−1v1w) and the input negative electrode doped neutral region width (DN−1v1w) by an input DC biasing voltage is used to adjust and control MR. Whereas adjustment and control of the thickness and width (DP−1v1t, DP−1v1w) of the input positive electrode doped neutral region and the thickness and width (DN−1v1t, DN−1v1w) of the input negative electrode doped neutral region by the input DC biasing voltage is used to adjust and control ML. Hence, in the present SAW transducers, oscillators, duplexer and SAW filters, the frequency of the IDTs is tunable and adjustable by applying and varying the DC biasing voltage.

Hence, at a given DC biasing voltage V_{DC1}, frequency f₁ of the surface acoustic waves is equal to: f₁=f₀+Δf_{MR1}+Δf_{ML1}, here f₀ is the basic frequency of the surface acoustic waves. Since wavelength λ of the surface acoustic waves to be excited is substantially equal to two times of the pitch value: λ=2×(220NS−1w)=2b, and the surface acoustic wave velocity increased from v₀ to v₁ due to reduced MR and ML, hence, frequency f₁ of the surface acoustic waves will increase and is equal to: f₁=v₁/2b(f₁>f₀). Here v₁ is the velocity of surface acoustic waves with a first DC biasing voltage V_{DC1} applied.

At a different DC biasing voltage V_{DC2}, the velocity of the surface acoustic waves will be v₂ and frequency will increase from the basic frequency f₀ to a new value f₂:f₂=f₀+Δf_{MR2}+Δf_{ML2}. Therefore for IDT1, if v₂>v₁>v₀, then f₂>f₁>f₀.

To simplify descriptions, contacts for RF signals: RFP and RFN, will not be shown in some of the subsequent figures. It is understood that RF contacts must be made to input positive electrodes, input negative electrodes, output positive electrodes and output negative electrodes preferably with DC blocking capacitors to supply or receive RF signals.

For the output inter digital transducer IDT2, frequency tuning and adjustment can be achieved according to this invention. FIG. 2F shows the same cross-sectional view of a tunable and adjustable SAW filter (200a) presented in FIG. 2D, except a first output DC biasing voltage V_{DC1′} is applied between the output positive electrode finger (250P−1) through an output positive electrode pad (250PM, FIG. 2A) and an output positive blocking inductor (LP1′), and the output negative electrode finger (250N−1) through the output negative electrode pad (250NM, FIG. 2A) and a negative blocking inductor (LN1′). The positive and negative blocking inductors are used to prevent leakages of RF signal to be received from the output positive electrode finger (250P−1) and output negative electrode finger (250N−1). The first output DC biasing voltage V_{DC1′} is applied to create and control an output positive electrode depletion region (DP−1′d1) with an output positive electrode depletion region thickness (DP−1′d1t) and to create and control an output negative electrode depletion region (DN−1′d1) with an output negative electrode depletion region thickness (DN−1′d1t). The output negative electrode depletion region thickness (DN−1′d1t) is substantially the same in magnitude as the output positive electrode depletion region thickness (DP−1′d1t). It should be noted that due to the formation of the output positive and negative electrode depletion regions (DP−1′d1, DN−1′d1), the output electrode doped region spacing widths or the first piezoelectric layer width (DNP−1′v1aw or DNP−1′v1bw) between the output positive electrode doped region (DP−1′v1) and the output negative electrode doped region (DN−1′v1) are increased from (DNP−1′aw, DNP−1′bw) in FIG. 2D.

The creation of the output negative electrode depletion region (DN−1′d1) and output positive electrode depletion region (DP−1′d1) and the thickness of them (DN−1′d1t, DP−1′d1t) are controlled by the polarity and magnitude of the first output DC biasing voltage V_{DC1′}. Here V_{DC1′} could be a positive or negative in polarity but with a small magnitude. The application of the V_{DC1′} and the creation of the depletion regions (DP−1′d1 and DN−1′d1) result in an output negative electrode doped neutral region thickness and width (DN−1′v1t and DN−1′v1w) and an output positive electrode doped neutral region thickness and width (DP−1′v1t, DP−1v1′w). The thicknesses and widths of the output positive and negative doped neutral regions are smaller than the output electrode doped region thicknesses and widths (DP−1′t and DN−1′t, DP−1′w and DN−1′w, in FIG. 2D). Therefore, the mass of loading associated with the output positive electrode finger (250P−1) which is the sum of mass of the output positive electrode doped neutral region (DP−1′v1) and mass of the output positive electrode finger (250P−1) will decrease. Whereas the mass of loading associated with the output negative electrode finger (250N−1) which is equal to the sum of mass of output negative electrode doped neutral region (DN−1′v1) and mass of output negative electrode finger (250N−1) also deceases simultaneously due to the formation of the output negative electrode depletion region (DN−1′d1). The decrease in mass of loading will cause an increase in the velocity of the surface acoustic waves (240) and an increase in the frequency of the surface acoustic waves from the basic frequency f₀ to a new value f₁. Here f₀ is the frequency when there is no positive and negative electrode depletion regions. When the total masse of the output positive and negative electrode fingers and the electrode doped neutral regions is decreased, there is a decrease in the mass loading effect and hence a mass loading frequency difference Δf_{ML1}=f₁−f₀.

Now considering the effect of metallization ratio MR, which is defined as the ratio between the output positive (or negative) electrode doped region width to the pitch value. In FIG. 2E, MR=(DP−1′v1w)/(250PS−1w)=(DP−1′v1w)/b (or (DN−1′v1w)/(250NS−1w)=(DN−1′v1w)/b) is reduced from the MR value in FIG. 2D. With a fixed ML, when the MR is decreased, the effects on surface acoustic wave propagation decrease and the velocity of surface acoustic waves increases: the frequency of surface acoustic waves increases. The frequency difference due to metallization ratio or metallization ratio frequency difference is given by Δf_{MR}. Due to the formation of the output positive and negative electrode depletion regions with the application of V_{DC1′}, MR decreases and the frequency of the surface acoustic waves increases.

According to this invention, the adjustment and control of the output positive electrode doped neutral region width (DP−1′v1w) and the output negative electrode doped neutral region width (DN−1′v1w) by an output DC biasing voltage is used to adjust and control MR. Whereas adjustment and control of the thickness and width (DP−1′v1t, DP−1′v1w) of the output positive electrode doped neutral region and the thickness and width (DN−1′v1t, DN−1′v1w) of the output negative electrode doped neutral region by the output DC biasing voltage is used to adjust and control ML. Hence, in the present SAW transducers, oscillators, duplexer and SAW filters, the frequency of the IDTs is tunable and adjustable by applying and varying the DC biasing voltage.

Hence, at a given DC biasing voltage V_{DC1′}, frequency f₁ of the surface acoustic waves is equal to: f₁=f₀+Δf_{MR1}+Δf_{ML1}, here f₀ is the basic frequency of the surface acoustic waves. Since wavelength λ of basic surface acoustic waves to be detected or received is substantially equal to two times of the pitch value: λ=2×(250NS−1w)=2×(250PS−1w)=2b′, and the surface acoustic wave velocity increased from v₀ to v₁ due to reduced MR and ML, hence, frequency f₁ of the surface acoustic waves to be detected or received will increase and is equal to: f₁=v₁/2b′(f₁>f₀). Here v₁ is the velocity of the surface acoustic waves with a first DC biasing voltage V_{DC1′} applied. It should be noted that the pitch value b′ of the output IDT (IDT2) is preferably selected to be the same as the pitch value b of the input IDT (IDT1): b′=b.

At a different output DC biasing voltage V_{DC2′} with a magnitude larger than V_{DC1′}, the velocity of the surface acoustic waves will be v₂ and frequency will increase from the basic frequency f₀ to a new value f₂:f₂=f₀+Δf_{MR2}+Δf_{ML2}. Therefore for IDT2, if v₂=v₁>v₀ then f₂>f₁>f₀.

In tunable and adjustable IDTs for SAW filters, SAW oscillators, switches or duplexers, it is preferable to design the input IDTs and the output IDTs so that at a giving DC biasing voltage V_{DC} and V_{DC′} (V_{DC}=V_{DC′}=V_{dc}), the frequency of surface acoustic waves to be excited and the frequency of the surface acoustic waves to be detected for the input and output inter digital transducers are identical. Therefore, it is preferable to have the respective dimensions for the input IDT to be the same as those for the output IDT, which include the dimensions for the following items: the input positive and negative electrode fingers, input positive and negative electrode doped regions, center-to-center distance between adjacent input positive and negative electrode doped regions, the output positive and negative electrode fingers, output positive and negative electrode doped regions, center-to-center distance between adjacent output positive and negative electrode doped regions.

It is also preferable to have the doping concentration and distribution of the input positive electrode doped regions to be the same as the output positive electrode doped regions, and to have the doping concentration and distribution of the input negative electrode doped regions to be the same as the output negative electrode doped regions, so that the tuning and adjustment of frequencies can be synchronized in IDT1 and IDT2.

The effects of change in DC biasing voltage on the frequency shift of SAW IDTs and devices are demonstrated in FIGS. 2G and 2H with DC biasing voltages V_{DC2} and V_{DC2′} applied to IDT1 and IDT2 respectively. FIG. 2G shows the same schematic cross-sectional view of a part of the IDT1 shown in FIG. 2E except with a different DC biasing voltage V_{DC2}. When the input DC biasing voltage V_{DC2} with a magnitude larger than that of V_{DC1} is applied between the input positive electrode finger (220P−1) and the output negative electrode finger (220N−1) to reverse biased the input positive and negative electrode doped regions, the cross-section areas of the positive and negative electrode doped neutral regions (DP−1v2, DN−1v2) decrease so that the input positive and negative electrode doped neutral region widths (DP−1v2w, DN−1v2w) and the input positive and negative electrode doped neutral region thicknesses (DP−1v2t, DN−1v2t) decrease from their respective values in FIG. 2E. Simultaneously, the thicknesses of the input positive and negative electrode depletion regions (DP−1d2, DN−1d2) increase to new input positive and negative electrode depletion region thicknesses (DP−1d2t, DN−1d2t) which is larger than the input positive and negative electrode depletion region thicknesses (DP−1d1t, and DN−1d1t) at the biasing voltage V_{DC1}. The input electrode doped region spacing widths or the first piezoelectric layer width (DNP−1v2aw or DNP−1v2bw) between the input positive electrode doped neutral region and the input negative electrode doped neutral region are larger than widths (DNP−1v1aw or DNP−1v1bw) in FIG. 2E following the increase in the input positive and negative electrode depletion region thicknesses (DN−1d2t, DP−1d2t).

The creation and the thicknesses (DN−1d2t, DP−1d2t) of the input positive and negative electrode depletion regions (DP−1d2, DN−1d2) are controlled by the polarity and magnitude of the input DC biasing voltage V_{DC2}. In FIG. 2G, V_{DC2} causes a decrease in the input positive and negative electrode doped neutral region widths and thicknesses (DP−1v2w, DN−1v2w, DP−1v2t, DN−1v2t) so that the mass of loading associated with the input positive and negative electrode fingers decreases. The mass of loading associated with the input positive electrode finger, which equals to the sum of mass of input positive electrode doped neutral region (DP−1v2) and mass of the input positive electrode finger (220P−1) decreases with the decrease in the cross-sectional area of (DP−1v2) from the cross-sectional area of (DP−1v1) in FIG. 2E. Simultaneously, the mass of loading associated with the input negative electrode finger, which equals to the sum of mass of the input negative electrode doped neutral region (DN−1v2) and mass of the input negative electrode finger (220N−1) also deceases with the decrease in the cross-sectional area of (DN−1v2) from the cross-sectional area of (DN−1v1). Due to the decreases in the input positive and negative electrode doped neutral region widths (DP−1v2w, DN−1v2w), the metallization ratio is also reduced from the MR values in FIG. 2E. Hence, the applied DC voltage V_{DC2} reduces further (from when V_{DC1} is applied) the metallization ratio and more importantly the mass loading so that the surface acoustic wave velocity is increased to v₂>v₁>v₀. Hence, the new frequency f₂ of the surface acoustic waves to be excited in IDT1 is: f₂=v₂/2b and f₂>f₁>f₀.

Therefore, it is understood that when a maximum input DC biasing voltage is applied to reach a maximum input positive electrode depletion region thickness and a maximum input negative electrode depletion region thickness, the frequency of the surface acoustic waves to be excited in IDT1 is maximum and the input positive and negative electrode doped neutral regions have minimum widths and minimum thicknesses. Both widths and thicknesses of the input electrode doped neutral regions should be kept as small as possible according to this invention in order to increase the tuning sensitivity of the frequency by the input DC biasing voltages.

According to this invention, the adjustment and control of the input positive and negative electrode doped neutral region width by an input DC biasing voltage is used to adjust and control the metallization ratio. Whereas adjustment and control of the thickness and the width of the input positive and negative electrode doped neutral region by the input DC biasing voltage is used to adjust and control the mass loading. Hence, in the present SAW transducers, SAW filters, SAW oscillators and SAW duplexers, frequency of the input IDTs is tunable and adjustable by applying and varying the input DC biasing voltage.

FIG. 2H shows the same schematic cross-sectional view of a part of IDT2 shown in FIG. 2F except with a different output DC biasing voltage. When an output DC biasing voltage V_{DC2′} with a magnitude larger than that of V_{DC1′} is applied between the output positive electrode finger (250P−1) and the output negative electrode finger (250N−1) to reverse biased the positive and negative electrode doped regions, the cross-sectional areas of the positive and negative electrode doped neutral regions (DP−1′v2, DN−1′v2) decrease and the output positive and negative electrode doped neutral region widths (DP−1′v2w and DN−1v2w) and the output positive and negative electrode doped neutral region thicknesses (DP−1′v2t and DN−1′v2t) decrease from their respective values in FIG. 2F. Simultaneously, the thicknesses of the output positive and negative electrode depletion regions (DP−1′d2, DN−1′d2) increase to new output positive and negative electrode depletion region thicknesses (DP−1′d2t, DN−1′d2t) which is larger than the output positive and negative electrode depletion region thicknesses (DP−1′d1t, and DN−1′d1t) at V_{DC1′}. The output electrode doped region spacing widths or the first piezoelectric layer width (DNP−1′v2aw or DNP−1′v2bw) between the output positive electrode doped neutral region and the output negative electrode doped neutral region are larger than widths (DNP−1′v1aw or DNP−1′v1bw) in FIG. 2F following the increase in the output positive and negative electrode depletion region thicknesses (DN−1′d2t, DP−1′d2t).

The creation and the thicknesses (DP−1′d2t, DN−1′d2t) of the output positive and negative electrode depletion regions (DP−1′d2, DN−1′d2) are controlled by the polarity and the magnitude of the DC output biasing voltage V_{DC2′}. In FIG. 2H, V_{DC2′} has a negative polarity and a magnitude larger than V_{DC1′}, which causes a decrease in the output positive and negative electrode doped neutral region widths and thickness (DP−1′v2w, DN−1′v2w, DP−1′v2t, DN−1′v2t) so that the mass of loading associated with the output positive and negative electrode fingers decreases. The mass of loading associated with output positive electrode finger (250P−1), which equals to the sum of mass of the output positive electrode doped neutral region (DP−1′v2) and the mass of the output positive electrode finger (250P−1), decreases with the decrease in the cross-sectional area of (DP−1′v2) from the cross-sectional area of (DP−1′v1) in FIG. 2F. Simultaneously, the mass of loading associated with the output negative electrode finger (259N−1), which equals to the sum of mass of output negative electrode doped neutral region (DN−1′v2) and mass of output negative electrode finger (250N−1), also deceases with the decrease in the cross-sectional area of (DN−1′v2) from the cross-sectional area of (DN−1′v12) in FIG. 2F. Due to the decreases in the output positive and negative electrode doped neutral region widths (DP−1′v2w, DN−1′v2w) from widths (DP−1′v1w, DN−1′v1w), the metallization ratio is also reduced from the MR values in FIG. 2E. Hence, the applied DC voltage V_{DC2′} reduces further (from when V_{DC1′} is applied) the MR and more importantly the ML so that the surface acoustic wave velocity is increased to v₂>v₁>v₀. Hence, the new frequency f₂ of the surface acoustic waves to be detected or received in IDT2 is equal to: f₂=v₂/2b′ and f₂>f₁>f₀.

Therefore, it is understood that when a maximum output DC biasing voltage is applied to reach a maximum output positive electrode depletion region thickness and a maximum output negative electrode depletion region thickness, the frequency of the surface acoustic waves to be detected or received in IDT2 is maximum and the output positive and negative electrode neutral regions have minimum widths and minimum thicknesses. Both widths and thickness of the output electrode doped neutral regions should be kept as small as possible according to this invention in order to increase the tuning sensitivity of the frequency by the DC biasing voltages.

According to this invention, the adjustment and control of the output positive and negative electrode doped neutral region widths by an output DC biasing voltage is used to adjust and control the metallization ratio whereas adjustment and control of output positive and negative electrode doped neutral region thickness by the output DC biasing voltage is used to adjust and control the mass loading. Hence, in the present SAW transducers, SAW filters, SAW oscillators and SAW duplexers, the frequency of the output IDTs is tunable and adjustable by applying and varying the output DC biasing voltage.

The temperature stability of a SAW device is characterized by the temperature coefficient of frequency (TCF), i.e. the fractional change of a specific frequency f with the temperature T as given by:

TCF=(1/f)(δf/δT)=TCV−TCE

Here, TCV is the temperature coefficient of velocity: TCV=(1/v)(δv/δT) and v is the velocity of the surface acoustic waves. TCE is the temperature coefficient of elasticity which is defined as the thermal expansion coefficient of the substrate in the propagation direction of the SAW.

Several piezoelectric materials such as LiNbO₃ and LiTaO₃ have negative TCF values and they become soft when temperature is increased, so that the frequencies of the fabricated tunable SAW transducers, filters, oscillators or duplexers may shift with the variation of the temperatures. In order to maintain frequency stability during operation, certain temperature compensation means should be adopted according to this invention. One possible method is to deposit a temperature compensation layer (280, FIG. 2I) with a temperature compensation layer thickness (280t) which could be an amorphous SiO₂ layer on the inter digital transducers (an IDT1 (220) is shown as an example in FIG. 21). One other method is to deposit reflectors (not shown) on a traditional LiNbO₃ and LiTaO₃ substrate. In a temperature compensation material such as amorphous SiO₂, mechanical stiffness increases with the increase in temperature T, resulting in positive TCE and TCV, so that the magnitude of the original negative TCF of the SAW transducers is reduced. To achieve the best results, both thickness of the temperature compensation layer and deposition conditions should be controlled. For piezoelectric materials with positive intrinsic TCF values, temperature compensation layer other than SiO₂ should be used.

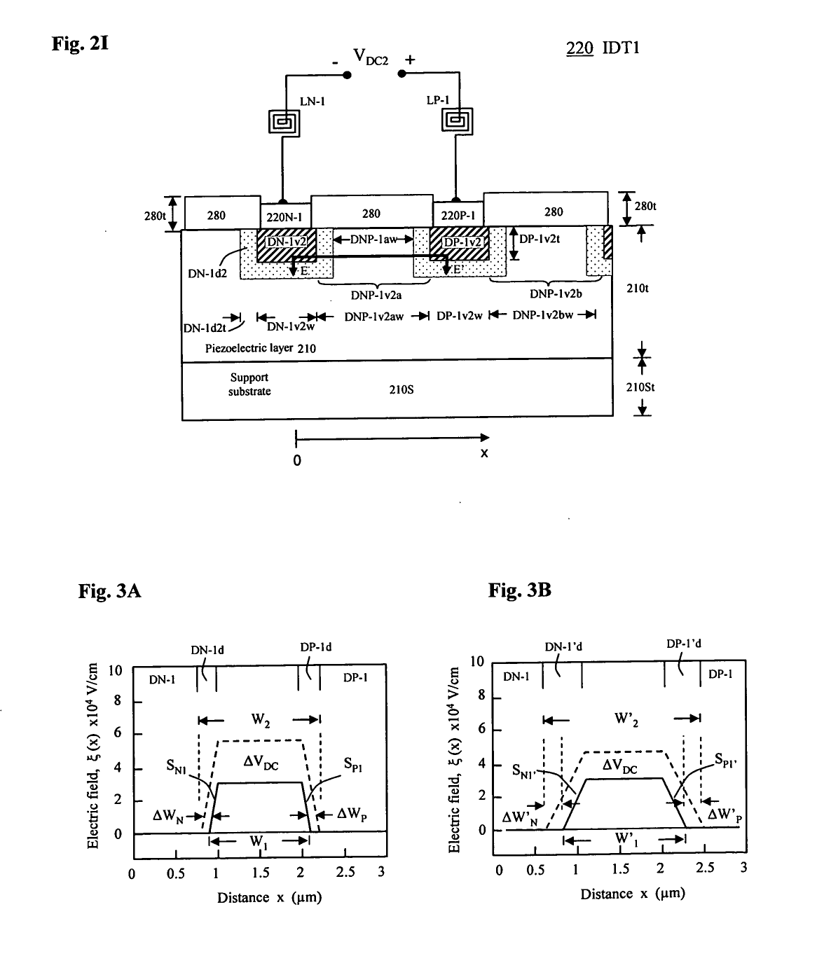

The effect of doping concentration in the positive and negative electrode doped regions of the IDTs on the tuning and adjustment of the electrode depletion regions and the electrode doped neutral regions are shown in FIGS. 3A and 3B. FIG. 3A shows the variation of electric field ξ(x) with distance x along the line E-E′ in the IDT1 shown in FIG. 2I with a high doping concentration N_{D} and N_{A}. It is noted that the variation of electric filed ξ(x′) with distance x′ along a line similar to E-E′ in FIG. 2I for IDT2 will be similar or the same when fabricated with the same N_{D} and N_{A}. In the first piezoelectric layer (210) which is un-doped and intrinsic, value of ξ(x) is essentially constant (as shown in the central region of the curves in FIG. 3A). In the input negative electrode depletion region (DN1d2 or DN−1d), the value of ξ(x) varies with distance with a relatively large magnitude of slope S_{N1} which is proportional to the ionized impurity concentration N⁺_{D} in the input negative electrode doped region. In the input positive electrode depletion region (NP−1d2 or DP−1d), the value of ξ(x) also varies with distance with a relatively large magnitude of slope S_{P1} which is proportional to ionized impurity concentration N⁻_{A}. Although the doping level in the input negative electrode doped region N_{D} and the doping level in the input positive electrode doped region N_{A} can be made different, it is preferred to make them substantially the same so that the magnitude of electric field slope S_{N1} in the input negative electrode doped region is substantially equal to magnitude of electric field slope S_{P1} in the input positive electrode doped region. This will ensure that the change in the input negative electrode depletion region width ΔW_{N} with the change of DC biasing voltage ΔV_{DC} is the same as the change in the input positive electrode doped region width ΔW_{P} and allow the change of piezoelectric active region more symmetrical with the change of the DC biasing voltage ΔV_{DC}. (Please be noted that the electrode depletion region width here has the same meaning as the electrode depletion region thickness described before.) The total increase in the depletion region width ΔW due to the biasing voltage change ΔV_{DC} is given by: ΔW=ΔW_{N}+ΔW_{P}=W₂−W₁. It is noted that the doping concentrations in the output IDTs and reflectors may be advantageously selected to be the same as that in the input IDTs and reflectors so that tuning sensitivity of the frequency for the surface acoustic waves is the same in the input IDTs and in the output IDTs.

FIG. 3B shows the variation of electric field ξ(x) with the distance x for another SAW device with a smaller doping concentrations: N_{D}′<N_{D} and N_{A}′<N_{A}. In FIG. 2B, the input negative electrode depletion region and the input positive electrode depletion region is given by DN−1′d and DP−1′d. As the magnitude of slope S_{N1′} in the input negative electrode depletion region is proportional to N_{D}′ and the magnitude of slope S_{P1′} in the input positive electrode depletion region is proportional N_{A}′, the magnitude of S_{N1′} and S_{P1′} are smaller than S_{P1} and S_{N1} in FIG. 3A. The change in the input negative electrode depletion region width ΔW′_{N} and in the input positive electrode depletion region width ΔW′_{P} with the change of the DC biasing voltage ΔV_{DC} is larger than that ΔW_{N} and ΔW_{P} shown in FIG. 3A. The total increase in the depletion region width ΔW due to the biasing voltage change ΔV_{DC} is given by: ΔW′=ΔW′_{N}+ΔW′_{P}=W′₂−W′₁>ΔW. The doping concentrations in the output IDTs and reflectors may advantageously be selected to be same as that in the input IDTs and reflectors so that tuning sensitivity of the frequency for the surface acoustic waves is the same. Therefore the doping concentration N_{A} and N_{D} in the input electrode doped regions and output electrode doped regions are adjusted according to the sensitivity required and to the tuning and adjustment frequency range of the surface acoustic waves by the DC biasing voltage.

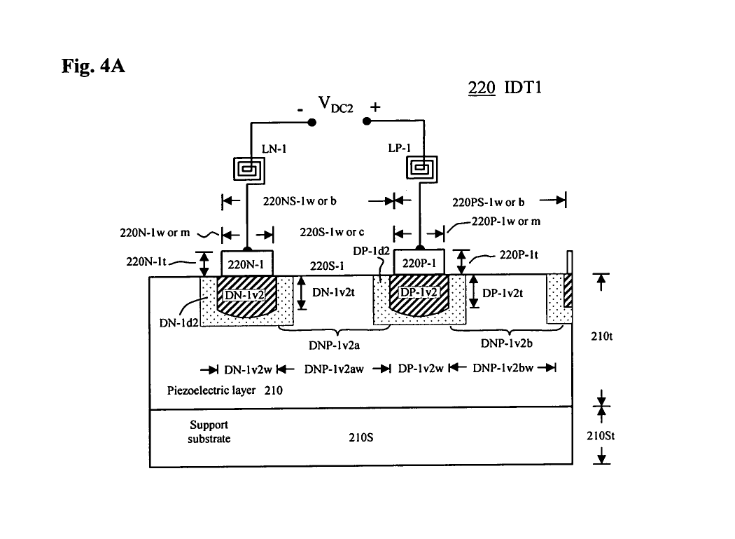

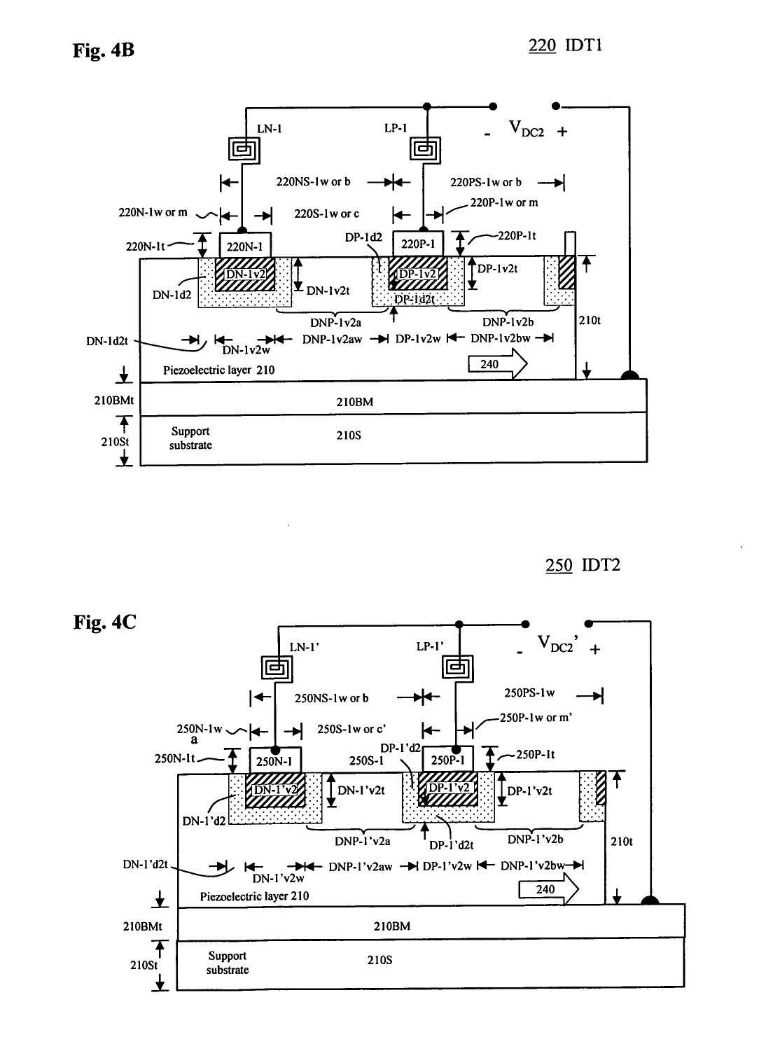

FIG. 4A is a schematic cross-sectional view of a part of the input IDT2 in the SAW filter (200a in FIG. 2A) taken along line A-A′. It shows the thickness of the input positive and negative electrode depletion region (DP−1d2, DN−1d2) are not a constant across the whole region. When the distance effect of the intrinsic piezoelectric layer (210) is considered, the thickness of the input negative electrode depletion region (DN−1d2) decreases towards the central area. This decrease also occurs in the thickness of the input positive electrode depletion region (DP−1d2). It is anticipated that similar situation will happen in the output positive and negative electrode depletion regions. The non-uniform electrode depletion region thickness may lead to a non-uniform mass loading for a given electrode doped region.

Since a constant potential difference is present in the electrode doped neutral regions (DN−1v2, DP−1v2), the electrode depletion regions (DN−1d2, DP−1d2) will not be uniform. Due to the non-uniform electrode depletion region thickness, at different locations in the boundary between the input positive electrode doped neutral region and the input positive electrode depletion region and at different locations in the boundary between the input negative electrode doped neutral region and the input negative electrode depletion region, the effective widths (the sum of the thicknesses of the two adjacent electrode depletion regions and the space between the two electrode depletion regions) of the first piezoelectric layer (DNP−1v2aw or DNP−1v2bw) are different. As shown in FIG. 4A, the thickness of the electrode depletion regions are the smallest at the center and the bottom of the electrode doped regions and they increases towards the two sides, therefore, the effective width of the first piezoelectric layer is larger near the central and the bottom of the input electrode doped regions. Due to the non-uniform width distribution of the electrode depletion regions with the position, the mass loading effect on the shift of frequency may not be uniform. To overcome this drawback, an improved SAW transducer structures with a bottom electrode layer as shown in FIGS. 4B and 4C is provided to improve the uniformity of the electrode depletion region thickness, according to another embodiment of the invention.

FIG. 4B is a schematic cross-sectional view of a IDT1 (220) in a tunable and adjustable SAW filter similar to the SAW filter (200a) shown in FIG. 2A, showing two adjacent input electrode fingers (220N−1, 220P−1) on the embedded (positive or negative) electrode doped neutral regions (DN1−v2, DP−1v2). A bottom electrode layer (210BM) having a bottom electrode layer thickness (210BMt) is sandwiched between the support substrate (210S) and the first piezoelectric layer (210) according to this invention. It should be emphasized that in this structure, the input first doping type could be p-type or n-type and the input second doping type could also be p-type or n-type. And the input second doping type is preferably selected to be the same as the input first doping type. The input positive electrode finger (220P−1) makes an ohmic contact to the input positive electrode doped neutral region (DP−1v2) and the input negative electrode finger (220N−1) makes an ohmic contact to the input negative electrode doped neutral region (DN−1v2). In FIG. 4B, (220P−1) and (220N−1) are connected together through an input positive blocking inductor (LP−1) and an input negative blocking inductor (LN−1) to a negative terminal of a input DC biasing source V_{DC2}, whereas the bottom electrode layer (210BM) is connected to a positive terminal of the DC biasing source V_{DC2}. Although the doping types and the biasing polarity for IDT1 in FIG. 4B are different from IDT1 shown in FIGS. 2C, 2E and 2G, the elements in FIG. 4B are marked the same way as the IDT1 in FIGS. 2C, 2E and 2G for convenience.

In FIG. 4B, the value of the V_{DC2} is regulated and the polarity of it is adjusted in order to achieve control and regulation for the input positive electrode depletion region thickness (DP−1d2t), the input negative electrode depletion region thickness (DN−1d2t), the input positive electrode doped neutral region thickness and width (DP−1v2t, DP−1v2w) and the input negative electrode doped neutral region thickness and width (DN−1v2t, DN−1v2w). This in turn regulates and changes the input positive electrode loading mass (the sum of mass of (DP−1v2) and mass of (220P−1)) and the input negative electrode loading mass (the sum of mass of (DN−1v2) and mass of (220N−1)) to achieve a mass loading frequency difference Δf_{ML} for the surface acoustic waves (240) to be excited (from the basic frequency value f₀ at zero biasing voltage). When the input negative electrode depletion region thickness (DN−1d2t) and the input positive electrode depletion region thickness (DP−1d2t) are increased by an increase in the magnitude of the reverse DC biasing voltage V_{DC2}, the frequency of the surface acoustic waves will increase due to decreases in the input positive electrode loading mass and in the input negative electrode loading mass. When the input negative electrode depletion region thickness (DN−1d2t) and the input positive electrode depletion region thickness (DP−1d2t) are decreased by a decrease in the magnitude of the reverse DC biasing voltage V_{DC2} or by reversing the polarity of V_{DC2} to forward biasing, the frequency of surface acoustic waves will decrease due to the increase in the input positive and negative electrode loading masses as a result of increases in the thicknesses and widths of the input negative and positive electrode doped neutral regions. The mass loading frequency difference Δf_{ML}, combined with the metallization ratio frequency difference Δ_{f}_{MR} due to the decrease in metallization ratio MR will produce the overall frequency difference Δf_{T} from the basic frequency f₀.

As materials of the input positive doped region and input negative doped region are selected to be a piezoelectric semiconductor having a substantially large energy gap, unwanted leakage current can be kept small when the DC biasing voltage is applied. Materials of the bottom electrode layer (210BM) may be selected from a group of metals and doped semiconductors, preferably doped piezoelectric semiconductors in the group of: Ti, Al, W, Pt, Mo, Cr, Pd, Ta, Cu, Cr, Au, Ni, Ag, Ru, Ir, AlN, GaN, AlGaN, ZnO, GaAs, AlAs, AlGaAs and their combinations.

FIG. 4C shows a schematic cross-sectional view of IDT2 in a frequency tunable and adjustable SAW filter similar to the SAW filter (200a) in FIG. 2A, showing two adjacent output electrode fingers (250N−1, 250P−1) on the embedded positive and negative electrode doped region (DN−1′v2, DP−1′v2). A bottom electrode layer (210BM) having a bottom electrode layer thickness (210BMt) is sandwiched between the support substrate (210S) and first piezoelectric layer (210) according to this invention. In this structure, the output first doping type could be p-type or n-type, and the output second doping type could also be p-type or n-type. And the output second doping type is preferably selected to be the same as the output first doping type. The output positive electrode finger (250P−1) makes an ohmic contact to the output positive electrode doped neutral region (DP−1′v2), and output negative electrode finger (250N−1), which make another ohmic contact to the output negative electrode doped neutral region (DN−1′v2). In FIG. 4C, (250P−1) and (250N−1) are connected together through an output positive blocking inductor (LP−1′) and an output negative blocking inductor (LN−1′) to a negative terminal of a DC biasing source V_{DC2′} whereas the bottom electrode layer (210BM) is connected to a positive terminal of the DC biasing source V_{DC2′}. Although the doping types and biasing polarity for IDT2 in FIG. 4C are different from IDT2 shown in FIGS. 2D, 2F and 2H, the elements in FIG. 4C are marked as the same way as the IDT2 in FIGS. 2D, 2F and 2H for convenience.

In FIG. 4C, value of the V_{DC2′} is regulated and the polarity of it is adjusted in order to achieve control and regulation for the output positive electrode depletion region thickness (DP−1′d2t), the output negative electrode depletion region thickness (DN−1′d2t), the output positive electrode doped neutral region thickness and width (DP−1′v2t, DP−1′v2w) and the output negative electrode doped neutral region thickness and width (DN−1′v2t, DN−1′v2w). This in turn regulates and changes the output positive electrode loading mass (the sum of mass of (DP−1′v2) and mass of (250P−1)) and the output negative electrode loading mass (the sum of mass of (DN−1′v2) and mass of (250N−1)) to effect a mass loading frequency difference Δf_{ML} for the surface acoustic waves (240) to be received (from a basic frequency value f₀ at zero biasing voltage V_{DC2′}). When the output negative electrode depletion region thickness (DN−1′d2t) and the output positive electrode depletion region thickness (DP−1′d2t) are increased by an increase in the magnitude of the reverse DC biasing voltage V_{DC2′}, the frequency of the surface acoustic waves to be detected will increase due to decreases in the output positive electrode loading mass and in the output negative electrode loading mass. When the output negative electrode depletion region thickness (DN−1′d2t) and the output positive electrode depletion region thickness (DP−1′d2t) are decreased by a decrease in the magnitude of the reverse DC biasing voltage or by reversing the polarity of V_{DC2′} to forward biasing, the frequency of the surface acoustic waves to be detected will decrease due to the increase in the output positive and negative electrode loading masses as a result of increases in the thicknesses and widths of the output negative and positive electrode doped neutral regions. The mass loading frequency difference Δf_{ML} combined with the metallization ratio frequency difference Δf_{MR} due to the decrease in metallization ratio will produce the overall frequency difference Δf_{T} from the basic frequency f₀.

As materials of the output positive doped region and output negative doped region are selected to be a piezoelectric semiconductor having a substantially large energy gap, unwanted leakage current can be kept small when the DC biasing voltage is applied. Materials of the bottom electrode layer (210BM) may be selected from a group of metals and doped semiconductors, preferably doped piezoelectric semiconductors in the group of Ti, Al, W, Pt, Mo, Cr, Pd, Ta, Cu, Cr, Au, Ni, Ag, Ru, Ir, AlN, GaN, AlGaN, ZnO, GaAs, AlAs, AlGaAs and their combinations.

IDTs with Elevated Electrode Doped Regions:

For the SAW transducer structures provided in FIGS. 2B-2I and FIGS. 4A-4C, the positive and the negative electrode doped regions are embedded in the first piezoelectric layer (210). For the embedded electrode doped regions, the freedom of motion of the embedded electrode doped neutral regions as loading mass is restricted. Hence, the mass loading effects on the mass loading frequency difference Δf_{ML}, for the surface acoustic waves with the embedded electrode doped regions will be less. In order to increase the mass loading effects on Δf_{ML} and decrease the metallization ratio effects on Δf_{MR}, SAW structures with elevated electrode doped regions are provided in this invention.

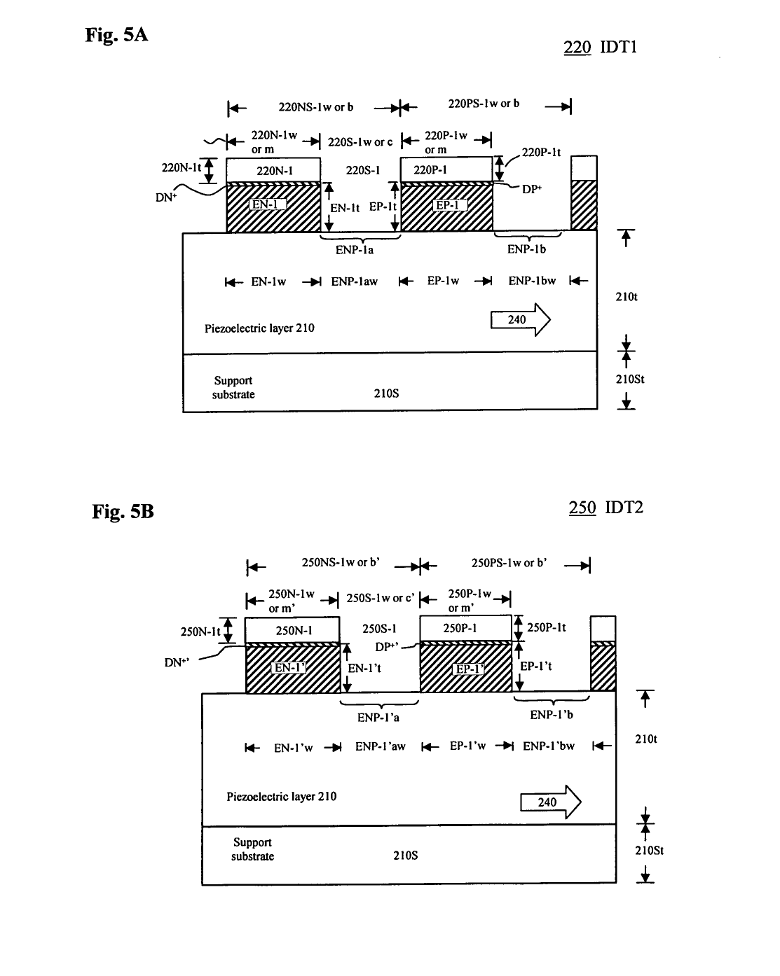

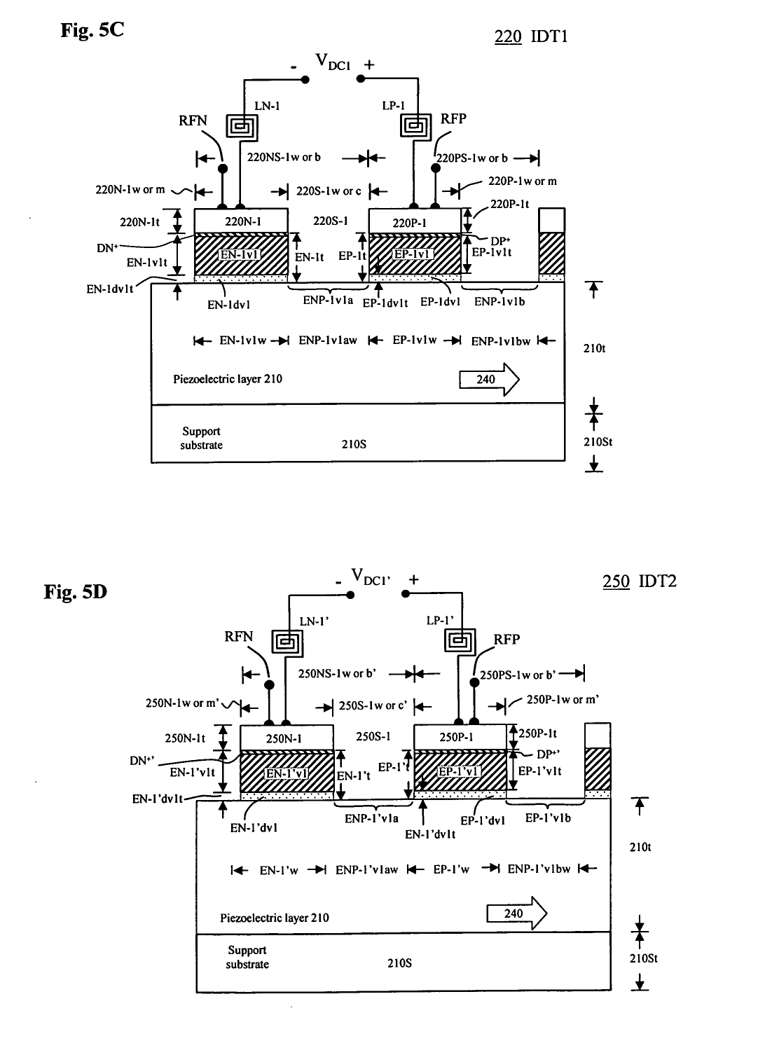

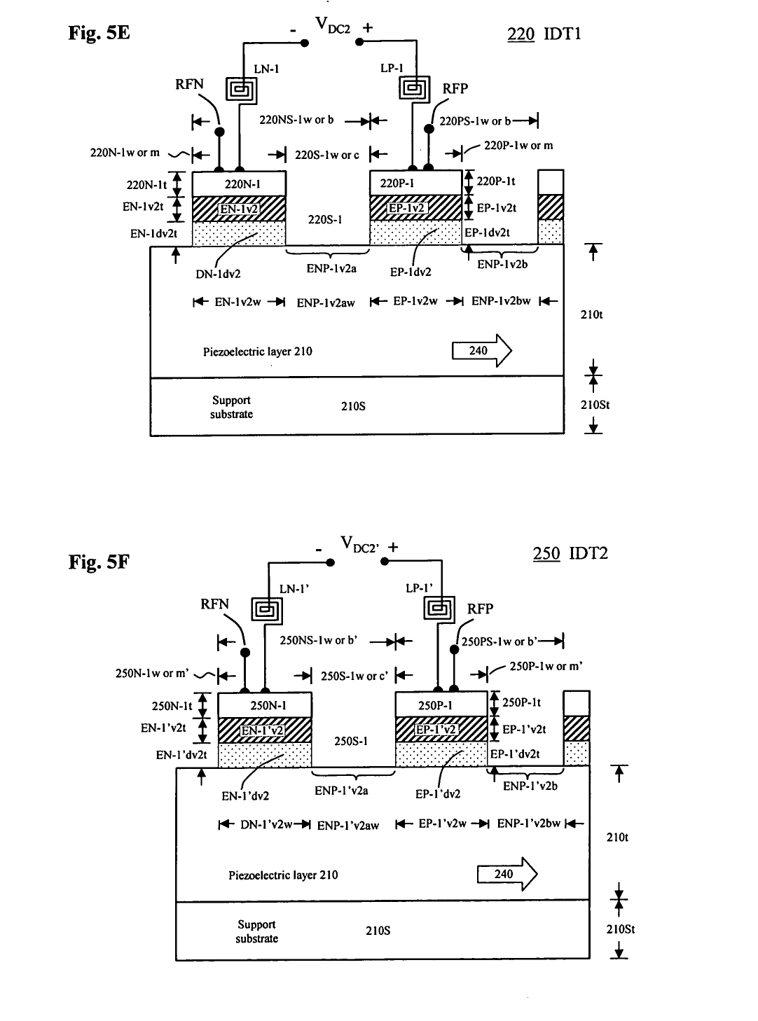

According to one embodiment of this invention, tunable SAW transducers with a plurality of elevated input and output electrode doped regions are provided in FIGS. 5A-5F. FIG. 5A is a schematic cross-sectional view of a tunable SAW filter (220a) taken along line A-A′ in FIG. 2A, showing a part of the input inter digital transducer IDT1 (220) on a first piezoelectric layer (210) having a first piezoelectric layer thickness (210t) on top of a support substrate (210S) having a support substrate thickness (210St). FIG. 5A shows an elevated input positive electrode doped region (EP−1) with an elevated input positive electrode doped region width (EP−1w) and an elevated input positive electrode doped region thickness (EP−1t) and an elevated input negative electrode doped region (EN−1) with an elevated input negative electrode doped region width (EN−1w) and an elevated input negative electrode doped region thickness (EN−1t). The elevated input positive electrode doped region (EP−1) has an input first doping type (which could be p-type or n-type) and is created on top of the first piezoelectric layer (210). An input positive electrode finger (220P−1) with an input positive electrode finger width (220P−1w or m) (which is substantially the same as (EP−1w)) and an input positive electrode finger thickness (220P−1t) is deposited on top of and aligned to the elevated input positive electrode doped region (EP−1). The elevated input negative electrode doped region (EN−1) of an input second doping type (which could be n-type or p-type and could be either the same as or opposite to the input first doping type) is created on top of the first piezoelectric layer (210) to form the elevated doped region structure. An input negative electrode finger (220N−1) with an input negative electrode finger width (220N−1w or m) (which is substantially the same as the elevated input negative electrode doped region width (EN−1w)) and an input negative electrode finger thickness (220N−1t) is deposited on top of and aligned to the elevated input negative electrode doped region (EN−1). Here, the elevated input positive electrode doped region (EP−1) is electrically conducting and forms a part of mass loading together with the input positive electrode finger (220P−1) and the elevated input negative electrode doped region (EN−1) is electrically conducting and forms the other part of mass loading together with the output negative electrode finger (220N−1).

Since the input positive and negative electrode finger widths (220P−1w, 220N−1w) are substantially the same as the elevated input electrode doped region widths (EP−1w, EN−1w), width (ENP−1aw, ENP−1bw) of the elevated input electrode doped region spacing (ENP−1a and ENP−1b) are essentially the same as the width (220S−1w or c) of the input electrode spacing region (220S−1). In FIG. 5A, together with the input electrode finger width (m), the input electrode spacing region width defines a pitch (220NS−1w or b) which is equal to the sum of the input electrode finger width (220N−1w or 220P−1w or m) and the input electrode spacing region width (220S−1w or c). The wavelength λ₀ of the surface acoustic waves (240) to be excited is substantially equal to two times of the pitch value: 2×(220NS−1w)=2b.

In order to facilitate ohmic contacts, it is preferable to have a heavily doped surface layer on the elevated input positive electrode doped region (EP−1) and the elevated input negative electrode doped region (EN−1). FIG. 5A shows a heavily n⁺-doped DN⁺ layer on the n-type elevated input negative electrode doped region (EN−1) and a heavily p⁺-doped DP⁺ layer on the elevated p-type input positive electrode doped region (EP−1). Thicknesses of the DN⁺ layer and the DP⁺ layer should be kept small (in the order of 20 nm or less).

According to one other embodiment of this invention, a schematic cross-sectional view of an output inter digital transducer IDT2 (250) is shown in FIG. 5B with a plurality of elevated output positive electrode doped regions and a plurality of elevated output negative electrode doped regions on the first piezoelectric layer (210) having a first piezoelectric layer thickness (210t) on top of a support substrate (210S) having a support substrate thickness (210St). An elevated output positive electrode doped region (EP−1′) with an elevated output positive electrode doped region width (EP−1′w) and an elevated output positive electrode doped region thickness (EP−1′t) and an elevated output negative electrode doped region (EN−1′) with an elevated output negative electrode doped region width (EN−1′w) and an elevated output negative electrode doped region thickness (EN−1′t). The elevated output positive electrode doped region (EP−1′) has an output first doping type (which could be p-type or n-type). An output positive electrode finger (250P−1) with an output positive electrode finger width (250P−1w or m′) (which is substantially the same as the elevated output positive electrode doped region width (EP−1′w)) and an output positive electrode finger thickness (250P−1t) is deposited on top of and aligned to the elevated output positive electrode doped region (EP−1′). The elevated output negative electrode doped region (EN−1′) of an output second doping type (which could be n-type or p-type and could be either the same as the output first doping type or opposite to the output first doping type) is created on top of the first piezoelectric layer. An output negative electrode finger (250N−1) with an output negative electrode finger width (250N−1w or m′) (which is substantially the same as the elevated output negative electrode doped region width (EN−1′w)) and an output negative electrode finger thickness (250N−1t) is deposited on top of and aligned to the elevated output negative electrode doped region (EN−1′). Here, the elevated output positive electrode doped region (EP−1′) is electrically conducting and forms a part of mass loading together with the output positive electrode finger (250P−1) and the elevated output negative electrode doped region (EN−1′) is also electrically conducting and forms the other part of mass loading together with the output negative electrode finger (250N−1).

Since the output positive or negative finger widths (250P−1w, 250N−1w) are substantially the same as the elevated output electrode doped region widths (EP−1′w, EN−1′w), width (ENP−1′aw or ENP−1′bw) of the elevated output electrode doped region spacing (ENP−1′a or ENP−1′b) are essentially the same as the width (250S−1w) of the input electrode spacing region (220S−1). Together with the output electrode finger width (m′), the output electrode spacing region width (250S−1w or c′) defines a pitch (250NS−1w or b′) which is equal to the sum of the output negative or positive electrode finger width (250N−1w or 250P−1w or m′) and the output electrode spacing region width (250S−1w). The wavelength of the surface acoustic waves (240) to be received is substantially equal to two times of the pitch value: 2×(250NS−1w)=2b′.

In order to facilitate ohmic contacts, a heavily n⁺-doped DN⁺′ layer is deposited on the n-type elevated output negative electrode doped region (EN−1′) and a heavily p⁺-doped DP⁺′ layer is deposited on the p-type elevated output positive electrode doped region (EP−1′). Thicknesses of the DN⁺′ layer and the DP⁺′ layer should be kept small (in the order of 20 nm or less).

For IDTs provided in FIGS. 5A-5F, the support substrate (210S) is selected from a piezoelectric material group including: LiNbO₃, LiTaO₃, PZT, AlN, GaN, AlGaN, ZnO, GaAs, AlAs, AlGaAs, BaTiO₃, quartz and KNbO₃ Si, sapphire, quartz, glass, and plastic as long as they are piezoelectric with sufficiently large acoustic-electric coupling coefficients. The thickness of the support substrate is selected by considering the mechanical strength, thermal dissipation and acoustic properties requirements. The first piezoelectric layer (210) is also selected from a material group including: LiNbO₃, LiTaO3, PZT, MN, GaN, AlGaN, ZnO, GaAs, AlAs, AlGaAs, BaTiO₃, quartz and KNbO₃, as long as they are piezoelectric materials with sufficient coupling coefficient. When the material for the first piezoelectric layer is selected to be the same as the support substrate (210S), they can be combined into a single piezoelectric substrate.

Materials for the elevated input/output positive and negative electrode doped regions are selected from a group of piezoelectric semiconductors: AlN, GaN, AlGaN, ZnO, GaAs, AlAs, AlGaAs, as long as they are piezoelectric with sufficient acoustic coupling coefficients, are semiconducting and can be doped to an n-type and/or a p-type conductions.

Materials for the input/output positive and negative electrode fingers (220P−1, 220N−1, 250P−1 and 250N−1) and materials for the input/output positive and negative electrode pads (220PM, 220NM, 250PM and 250NM) are selected from a metal group including: Ti, Al, W, Pt, Mo, Cr, Pd, Ta, Cu, Cr, Au, Ni, Ag, Ru, Ir and other metals and their alloys. In order to have ohmic contacts between the input/output positive electrode fingers and the elevated input/output positive electrode doped regions and between the input/output negative electrode fingers and the elevated input/output negative electrode doped regions, the first layer of the input/output positive electrode fingers should have a large work function, preferably larger than the electron affinity of the piezoelectric semiconducting material for the elevated input/output positive electrode doped regions when doped to a p-type conduction. The first layer of the input/output negative electrode fingers should have a low work function, preferably close to electron affinity of the piezoelectric semiconducting material for the elevated input/output negative electrode doped regions when doped to an n-type conduction. Opposite will be true when the doping type is reversed.

Furthermore, it is preferable to select metals with smaller atomic weights such as Al, Ti for the input/output positive and negative electrode fingers. It is also preferable to have a reduced electrode finger thickness in order to decrease the mass loading effect due to the input positive and negative electrode fingers and the output positive and negative electrode fingers and in order to increase the tuning sensitivity of the frequency with varied DC voltages. The input/output positive and negative electrode finger thicknesses is preferably selected in a range of 10 to 400 nm and is more preferably selected in a range of 20 nm to 300 nm, dependent on the operation frequency and the frequency tuning range required. A multilayer metal structure involving at least two metal materials may be advantageously adopted to improve the adhesion of metal electrode layers and to reduce the contact resistance.

In the depletion regions of the elevated electrode doped regions and in the un-doped first piezoelectric layer (210), the charge carrier density is small (below 10¹⁰ cm⁻³), so that the electrical conductivity is very (low ˜10⁻¹⁰/ohm-cm or less) and the depletion region behaves as an insulator. Whereas in the neutral region of the elevated electrode doped regions, the carrier density is selected to be large (10¹⁴ to 10²¹ cm⁻³) and is more preferably selected in a range of 10¹⁵ to 10²⁰ cm⁻³ so that the electrical conductivity is large and the neutral region behaves as a conductor. In the heavily doped DP⁺ and DN⁺ regions, the carrier concentration is preferably to be more than 10²⁰ cm⁻³.

According to one embodiment of this invention, the elevated positive and negative electrode doped region thicknesses (EP−1t, EP−1′t, EN−1t, EN−1′t) are selected to be in a range of 10 to 2000 nm and more preferably to be in a range of 20 to 1000 nm, dependent on the operation frequency and the tuning range required. The selection of the positive electrode doped region thickness and negative electrode doped region thickness are thus determined by the frequency of surface acoustic waves, tuning and adjustment range of frequency, and the tuning sensitivity of the frequency required.

FIG. 5C shows the IDT1 (220) shown in FIG. 5A with a first input DC biasing voltage V_{DC1} applied through an input positive electrode pad and an input negative electrode pad (220PM, 220NM in FIG. 2A) and through an input positive blocking inductor (LP−1) and an input negative blocking inductor (LN−1) to the input negative electrode finger (220N−1) and the input positive electrode finger (220P−1). In FIG. 5C, the input first doping type is p-type and the input second doping type is n-type. The applied first input DC biasing voltage V_{DC1} creates an input negative electrode depletion region (EN−1dv1) and an input positive electrode depletion region (EP−1dv1). V_{DC1} also controls and regulates the input negative electrode depletion region thickness (EN−1dv1t), the input positive electrode depletion region thickness (EP−1dv1t) as well as the thickness (EP−1v1t) of the input positive electrode doped neutral region (EP−1v1) and the thickness (EN−1v1t) of the input negative electrode doped neutral region (EN−1v1) to achieve regulating and controlling of the input positive electrode loading mass and the input negative electrode loading mass. Here, the input positive electrode loading mass equals to the sum of mass of (EP−1v1) and mass of (220P−1), and the input negative electrode loading mass equals to the sum of mass of (EN−1v1) and mass of (220N−1).

The mass difference from the maximum mass (when no electrode depletion regions are present) causes a mass loading frequency difference Δf_{ML} for the surface acoustic waves (240) to be excited (from an basic frequency value f₀). When the input negative electrode depletion region thickness (EN−1dv1t) and the input positive electrode depletion region thickness (EP−1dv1t) are increased by an increase in the magnitude of a reverse DC biasing voltage, the velocity and the frequency of the surface acoustic waves (240) will increase due to a decrease in the input positive electrode loading mass and a decrease in the input negative electrode loading mass. When the thickness (EN−1dv1t) and the thickness (EP−1dv1t) are decreased by a decrease in the magnitude of the reverse DC biasing voltage or by reversing the polarity of V_{DC1} to forward biasing, the velocity and the frequency of the surface acoustic waves will decrease due to an increase in the input positive electrode loading mass and an increase in the input negative electrode loading mass.

As the components of loading mass associated with the input electrode fingers: the input electrode fingers (220P−1, 220N−1) and the input electrode doped neutral regions (EP−1v1, EN−1v1) are all elevated and are on the piezoelectric layer (210), the effect of mass loading on the mass loading frequency difference Δf_{ML}, with the same mass will be greater than that when the electrode doped regions are embedded in the piezoelectric layer (as shown in FIGS. 2C-2I and FIGS. 4A-4B). With the elevated input positive electrode doped neutral region (EP−1v1) and elevated input negative electrode doped neutral region (EN−1v1), the frequency tuning of the surface acoustic waves to be excited by the input DC biasing voltage will be more sensitive compared to that when the electrode doped regions are embedded within the piezoelectric layer.

It should also be noted that the metallization ratio frequency difference Δf_{MR} due to the MR change in this structure with the elevated electrode doped regions is relatively small as compared to the mass loading frequency difference Δf_{ML} and Δf_{MR} is also smaller than that in a structure with an embedded electrode doped regions.

As materials of the elevated input positive electrode doped regions and the elevated input negative electrode doped regions are selected to be a piezoelectric semiconductor having a substantially large energy gap, unwanted leakage current when the first input DC voltage V_{DC1} is applied can be kept small. The frequency of the surface acoustic waves is equal to: f₁=v₁/2×(220NS−1w)=v₁/2b, here v₁ is the velocity of the surface acoustic waves in the piezoelectric layer under the electrodes associated with the IDT1 (220) with biasing voltage V_{DC1}.

FIG. 5D shows the IDT2 (250) shown in FIG. 5B with a first output DC biasing voltage V_{DC1′} applied through an output positive electrode pad and an output negative electrode pad (250PM, 250NM in FIG. 2A) and through an output positive blocking inductor (LP−1′) and an output negative blocking inductor (LN−1′) to the output negative finger (250N−1) and the output positive electrode finger (250P−1). Here, the output first doping type is p-type and the output second doping type is n-type. The applied DC biasing voltage V_{DC1′} creates an output negative electrode depletion region (EN−1′dv1) and an output positive electrode depletion region (EP−1′dv1) and it controls and regulates the output negative electrode depletion region thickness (EN−1′dv1t), the output positive electrode depletion region thickness (EP−1′dv1t) as well as the thickness (EP−1′v1t) of the output positive electrode doped neutral region (EP−1′v1) and the thickness (EN−1′v1t) of the output negative electrode doped neutral region (EN−1′v1) to achieve regulating and controlling of the output positive electrode loading mass: the sum of mass of (EP−1′v1) and mass of (250P−1) and the output negative electrode loading mass: the sum of mass of (DN−1′v1) and mass of (250N−1).

The mass difference from the maximum mass (when no electrode depletion regions are present) causes a mass loading frequency difference Δf_{ML} for the surface acoustic waves to be received (from the basic frequency value f_{0′}). When the output negative electrode depletion region thickness (EN−1′dv1t) and the output positive electrode depletion region thickness (EP−1′dv1t) are increased by an increase in the magnitude of a reverse DC biasing voltage, the velocity and the frequency of the surface acoustic waves to be received will increase due to a decrease in the output positive electrode loading mass and a decrease in the output negative electrode loading mass. When the thicknesses (EN−1′dv1t, EP−1′dv1t) are decreased by a decrease in the magnitude of the reverse DC biasing voltage or by reversing the polarity of V_{DC1′} to forward biasing, the velocity and the frequency of surface acoustic waves will decrease due to increases in the output positive electrode loading mass and the output negative electrode loading mass.

As the components of the loading mass associated with the output electrode fingers: the output electrode fingers (250P−1, 250N−1) and the output electrode doped neutral regions (EP−1′v1, EN−1′v1) are all elevated, the effect of mass loading on the mass loading frequency difference Δf_{ML} with the same mass will be greater than that when the output electrode doped regions are embedded in the piezoelectric layer (FIGS. 2C-2I). With the elevated output positive electrode doped neutral region (EP−1′v1) and elevated output negative electrode doped neutral region (EN−1′v1), the frequency tuning of the surface acoustic waves by the output DC biasing voltage will be more sensitive compared to that when the electrode doped regions are embedded within the piezoelectric layer.

It should be noted that the metallization ratio frequency difference Δf_{MR} due to the metallization ratio change in this structure elevated electrode doped regions is relatively small as compared to the mass loading frequency difference Δf_{ML} and Δf_{MR} is also smaller than that in a structure with an embedded electrode doped regions.

As materials of the elevated output positive and negative electrode doped regions are selected to be a piezoelectric semiconductor having a substantially large energy gap, unwanted leakage current when the first output DC biasing voltage V_{DC1′} is applied can be kept small. Hence, the frequency of the surface acoustic waves is equal to: f_{1′}=v_{1′}/2×(250NS−1w)=v_{1′}/2b′, here v_{1′} is the velocity of surface acoustic waves in the piezoelectric layer under the electrodes associated with the output inter digital transducer IDT2 (250) with the first output DC biasing voltage V_{DC1′}.

In the tunable and adjustable IDTs for SAW filter, SAW oscillator, switches or duplexers, it is preferable to design the input IDTs and the output IDTs in a way so that at a giving DC biasing voltage V_{DC} and V_{DC}′ (V_{DC}=V_{DC}′=V_{dc}), the frequencies of the surface acoustic waves to be excited and to be detected for both transducers are equal. Therefore, it is preferable to have dimensions of the input positive electrode fingers, input negative electrode fingers, the elevated input positive electrode doped regions, the elevated input negative electrode doped regions, the center-to-center distance between adjacent input negative electrode doped region and input positive electrode doped region to be the same as the dimensions of corresponding elements in the output inter digital transducer IDT2. It is also preferable to have the doping concentration and distribution of the elevated input positive electrode doped region to be the same as that of the elevated output positive electrode doped region, whereas the doping concentration and distribution of the elevated input negative electrode doped region is preferably to be the same as that of the elevated output negative electrode doped region, so that the tuning and adjustment of frequencies can be synchronized.

The effects of the DC biasing voltage on the frequency tuning of the tunable SAW transducers with elevated electrode doped regions are similar to the effects on tuning of the tunable SAW transducers with embedded doped regions and will be described in IDTs provided in FIG. 5E and FIG. 5F. For simplicity reasons, the heavily p⁺-doped DP⁺ and DP^{+′} layers and the heavily doped n⁺-doped DN⁺ and DN^{+′} layers are not shown in FIG. 5E and 5F.

FIG. 5E shows the IDT1 shown in FIG. 5A with a second input DC biasing voltage V_{DC2} applied. Here, V_{DC2} has the same polarity as V_{DC1} but with a larger magnitude. The applied V_{DC2} creates a new input negative electrode depletion region (EN−1dv2) with a larger thickness (EN−1dv2t) than (EN−1dv1t) and a new input positive electrode depletion region (EP−1dv2) of a larger thickness (EP−1dv2t) than (EP−1dv1t). This produces a new input positive electrode doped neutral region (EP−1v2) of a smaller thickness (EP−1v2t) than (EP−1v1t) and a new input negative electrode doped neutral region (EN−1v2) of a smaller thickness (EN−1v2t) than (EN−1v1t). Hence, the applied V_{DC2} regulates and changes the input positive electrode loading mass: the sum of mass of (EP−1v2) and mass of electrode finger (220P−1). V_{DC2} also regulates and controls simultaneously the input negative electrode loading mass: the sum of mass of (EN−1v2) and mass of electrode finger (220N−1). The reduced amount in the sum of masses of (EN−1v2 and 220N−1) from the sum of masses of (EN−1 and 220N−1) effects a frequency increase Δf_{ML} from the basic frequency value f₀. Since the sum of masses of (EN−1v2 and 220N−1) is smaller than the sum of masses of (EN−1v1 and 220N−1) in FIG. 5C when the first input DC biasing voltage V_{DC1} was applied, V_{DC2} produces a new frequency f₂ which is higher than the frequency f₁ excited in IDT1 by V_{DC1}, hence f₂>f₁>f₀.

FIG. 5F shows the IDT2 shown in FIG. 5B with a second output DC biasing voltage V_{DC2′} applied. Here, V_{DC2′} has the same polarity as the first output DC biasing voltage V_{DC1′} but with a larger magnitude. The applied V_{DC2′} creates a new output negative electrode depletion region (EN−1′dv2) with a larger thickness (EN−1′dv2t) than (EN−1′dv1t) in FIG. 5D and a new output positive electrode depletion region (EP−1′dv2) of a larger thickness (EP−1′dv2t) than (EP−1′dv1t). This produce a new output positive electrode doped neutral region (EP−1′v2) of a smaller thickness (EP−1′v2t) than (EP−1′v1t) in FIG. 5D and a new output negative electrode doped neutral region (EN−1′v2) of a smaller thickness (EN−1′v2t) than (EN−1′v1t). Hence, the applied V_{DC2′} regulates and changes the output positive electrode loading mass: the sum of mass of (EP−1′v2) and mass of finger (250P−1), and to regulate and control simultaneously the output negative electrode loading mass: the sum of masses of (EN−1′v2) and finger (250N−1). The reduced amount in the sum of masses of (EN−1′v2) and (250N−1) from the sum of masses of (EN−1′, FIG. 5B) and (250N−1) effects an frequency increase Δf_{ML} from the basic frequency value f_{0′}. Since the sum of masses of (EN−1′v2 and 250N−1) is smaller than the sum of masses of (EN−1′v1 and 250N−1) in FIG. 5D when the first output DC biasing voltage V_{DC1′} was applied, V_{DC2′} produces a new frequency f_{2′} which is larger than the frequency f_{1′} excited in IDT2 by V_{DC1′}, hence f_{2′}>f_{1′}>f₀.

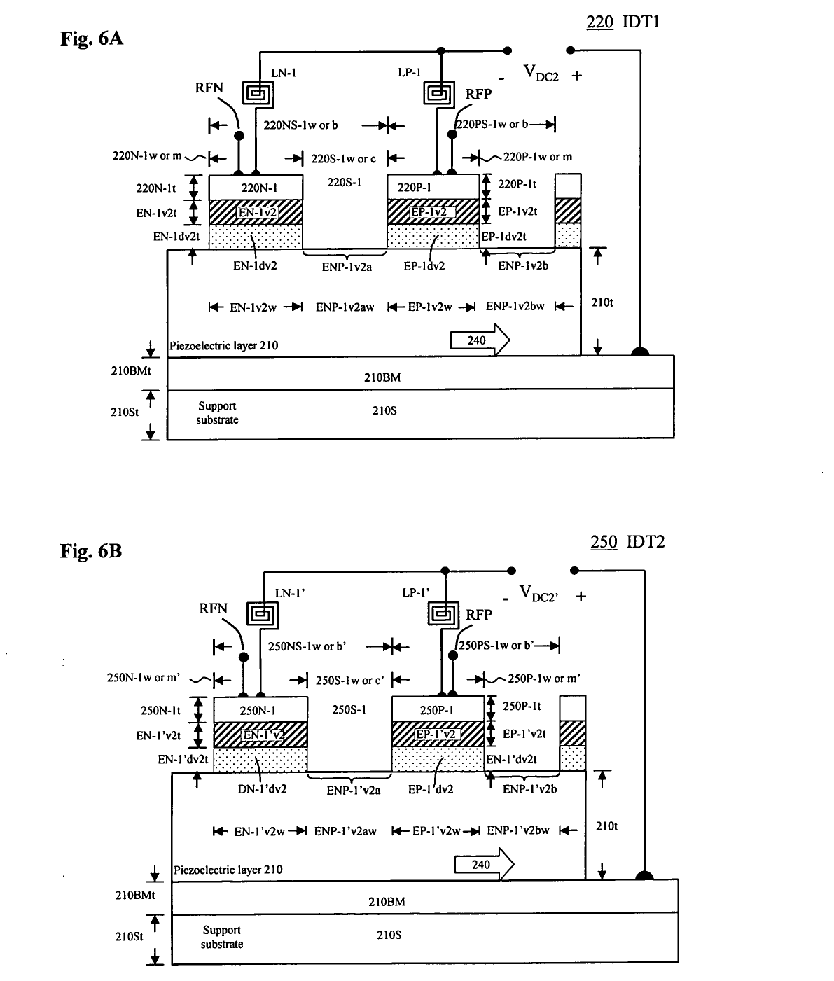

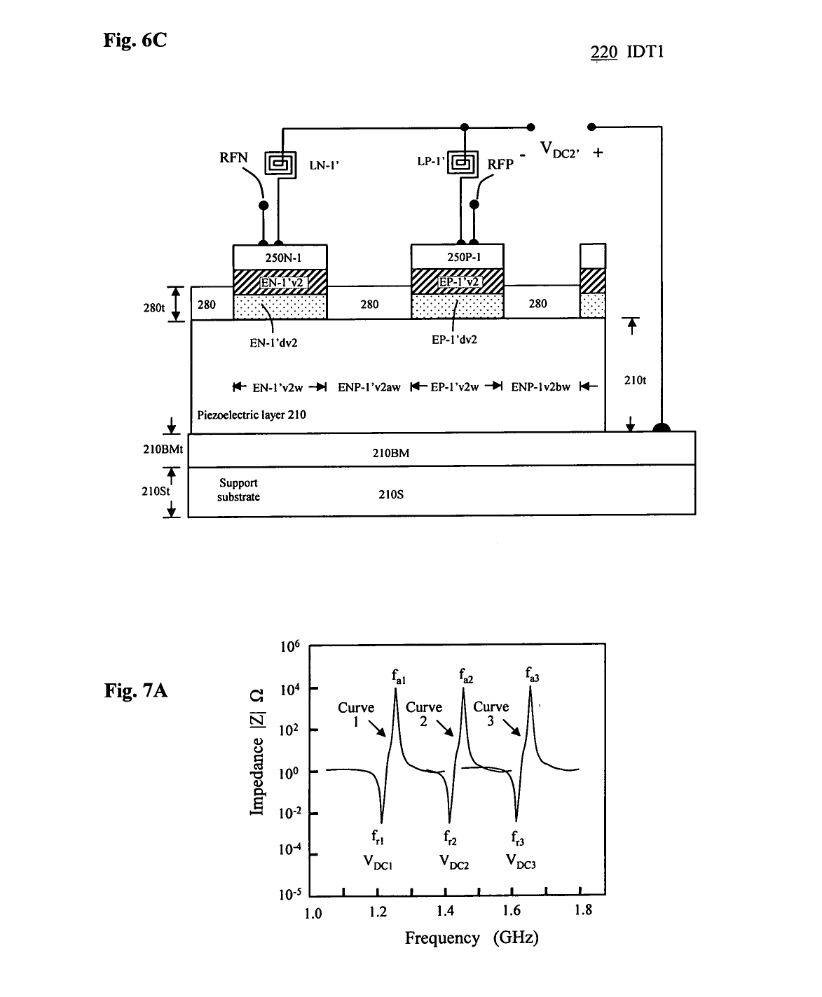

The performance of tunable SAW transducers with elevated electrode doped regions provided in FIGS. 5A-5F can be further improved by adopting a structure to be shown in FIGS. 6A-6C.

FIG. 6A is a schematic cross-sectional view of an IDT1 (220) considerably similar to the IDT1 shown in FIG. 5E, showing two adjacent input electrode fingers (220N−1, 220P−1) on the elevated input positive and negative electrode doped neutral regions (EP−1v2, EN−1v2). A bottom electrode layer (210BM) having a bottom electrode layer thickness (210BMt) is sandwiched between the support substrate (210S) and the first piezoelectric layer (210) according to this invention. It should be emphasized that in this structure, the input first doping type could be p-type or n-type, whereas the input second doping type could also be p-type or n-type and the input second doping type is preferably selected to be the same as the input first doping type. The input positive electrode finger (220P−1) makes an ohmic contact to the elevated input positive electrode doped neutral region (EP−1v2) and the input negative electrode finger (220N−1) makes an ohmic contact to the elevated input negative electrode doped neutral region (EN−1v2). In FIG. 6A, (220P−1) and (220P−1) are connected together through an input positive blocking inductor (LP−1) and an input negative blocking inductor (LN−1) to a negative terminal of an input DC biasing source V_{DC2}, whereas the bottom electrode layer (210BM) is connected to a positive terminal of the DC biasing source V_{DC2}. Although the doping types of the elevated positive and negative electrode doped regions and the biasing polarity for IDT1 in FIG. 6A are different from the IDT1 in SAW filter (200a), the elements in FIG. 6A are marked the same way as the SAW filter (200a in FIG. 2A) for convenience.

In FIG. 6A, the value of V_{DC2} is regulated and the polarity of it is adjusted in order to achieve control and regulation for the elevated input positive and negative electrode depletion region thicknesses (EN−1dv2t and EP−1dv2t), and the input positive and negative electrode doped neutral region thicknesses (EP−1v2t and EN−1v2t). This in turn regulates and changes the input positive electrode loading mass (the sum of mass of (EP−1v2) and mass of (220P−1)) and the input negative electrode loading mass (the sum of mass of (EN−1v2) and mass of (220N−1)) to effect a mass loading frequency difference Δf_{ML} for the surface acoustic waves (240) to be excited (from a basic frequency value f₀ at zero input biasing voltage). When the input negative electrode depletion region thickness (EN−1dv2t) and the input positive electrode depletion region thickness (EP−1dv2t) are increased by an increase in the magnitude of the reverse DC biasing voltage V_{DC2}, the frequency of the surface acoustic waves to be excited will increase due to a decreases in the input positive electrode loading mass and in the input negative electrode loading mass as a result of decreases in the input positive and negative electrode doped neutral region thicknesses. When the input negative electrode depletion region thickness (EN−1dv2t) and the input positive electrode depletion region thickness (EP−1dv2t) are decreased by a decrease in the magnitude of the reverse DC biasing voltage V_{DC2} or by reversing the polarity of V_{DC2} to forward biasing, the frequency of the surface acoustic waves to be excited will decrease due to an increases in the input positive and negative electrode loading masses as a result of increases in the input positive and negative electrode doped neutral region thickness (EP−1v2t and EN−1v2t). The metallization ratio MR frequency difference Δf_{MR} due to the decrease or increase in input DC biasing voltage is negligible for IDT1 with the elevated electrode doped regions.

As materials of the elevated input positive and negative doped regions are selected to be a piezoelectric semiconductor having a substantially large energy gap, unwanted leakage current can be kept small when the DC biasing voltage is applied. Materials of the bottom electrode layer (210BM) may be selected from a group of metals and doped semiconductors, preferably to be doped piezoelectric semiconductors including: Ti, Al, W, Pt, Mo, Cr, Pd, Ta, Cu, Cr, Au, Ni, Ag, Ru, Ir, AlN, GaN, AlGaN, ZnO, GaAs, AlAs, AlGaAs and their combinations.

FIG. 6B is a schematic cross-sectional view of an IDT2 (250) considerably similar to the IDT2 in FIG. 5F, showing a structure with elevated output positive and negative electrode doped regions (EP−1′v2, EN−1′v2) and two adjacent output electrode fingers (250N−1, 250P−1). A bottom electrode layer (210BM) having a bottom electrode layer thickness (210BMt) is sandwiched between the support substrate (210S) and first piezoelectric layer (210) according to this invention. It should be noted that in this structure, the output first doping type could be n-type or p-type, whereas the output second doping type could also be n-type or p-type. And the output second doping type is preferably selected to be the same as the output first doping type. The output positive electrode finger (250P−1) makes an ohmic contact to the elevated output positive electrode doped neutral region (EP−1′v2) and the output negative electrode finger (250N−1) makes an ohmic contact to the elevated output negative electrode doped neutral region (EN−1′v2). In FIG. 6B, fingers (250P−1) and (250N−1) are connected together through an output positive blocking inductor (LP−1′) and an output negative blocking inductor (LN−1′) to a negative terminal of an output DC biasing source V_{DC2′} whereas the bottom electrode layer (210BM) is connected to a positive terminal of the DC biasing source V_{DC2′}. Although the doping types of the elevated positive and negative electrode doped regions and the biasing polarity for IDT2 in FIG. 6B are different from the IDT2 in SAW filter (200a), the elements in FIG. 6B are marked the same way as the IDT2 in FIG. 2A for convenience.

The value of the DC biasing source V_{DC2′} is regulated and the polarity of it is adjusted in order to achieve control and regulation for the elevated output positive and negative electrode depletion region thicknesses (EP−1′dv2t, EN−1′dv2t), and the output positive and negative electrode neutral region thicknesses (EP−1′v2t, EN−1′v2t), hence to regulate and change the output positive electrode loading mass (the sum of mass of (EP−1′v2) and mass of (250P−1)) and the output negative electrode loading mass (sum of mass of (EN−1′v2) and mass of (250N−1)). The reduced loading mass effects a mass loading frequency difference Δf_{ML} for the surface acoustic waves (240) (from a basic frequency value at zero output biasing voltage). When the output negative electrode depletion region thickness (EN−1′dv2t) and the output positive electrode depletion region thickness (EP−1′dv2t) are increased by an increase in the magnitude of the reverse DC biasing voltage V_{DC2′}, the frequency of the surface acoustic waves to be detected will increase due to decreases in the output positive and negative electrode loading masses as a result of decreases in the output positive and negative electrode doped neutral region thicknesses. When the output negative electrode depletion region thickness (EN−1′dv2t) and the output positive electrode depletion region thickness (EP−1′dv2t) are decreased by a decrease in the magnitude of the reverse DC biasing voltage V_{DC2′} or by reversing the polarity of V_{DC2′} to forward biasing, the frequency of the surface acoustic waves to be detected will decrease due to increases in the output positive and negative electrode loading masses as a result of increases in the output positive and negative electrode doped neutral region thicknesses (EP−1′v2t, EN−1′v2t). The metallization ratio frequency difference Δf_{MR} due to the decrease or increase in output DC biasing voltage is negligible for the IDT2 with the elevated electrode doped regions.

The temperature stability of a SAW device is characterized by the temperature coefficient of the frequency (TCF), i.e., fractional change of a specific frequency f with the temperature T and it is given by:

TCF=(1/f)(δf/δT)=TCV−TCE

Here, TCV is the temperature coefficient of the velocity: TCV=(1/v)(δv/δT) and v is the velocity of the surface acoustic waves. TCE is temperature coefficient of elasticity which is defined as the thermal expansion coefficient of the substrate in the propagation direction of the SAW.

Several piezoelectric materials such as LiNbO₃ and LiTaO₃ have negative TCF values and they become soft when the temperature is increased, so that the frequencies of the fabricated tunable SAW transducers, filters, oscillators or duplexers may shift with the variation of the temperatures. In order to maintain frequency stability during operation, certain temperature compensation measures should be taken according to this invention. One possible method is to deposit a temperature compensation layer (e.g. an amorphous SiO₂ layer) on the inter digital transducers. One other method is to deposit reflectors (not shown) on a traditional LiNbO₃ and LiTaO₃ substrate. In a temperature compensation material such as amorphous SiO₂, mechanical stiffness increases with the increase in temperature, resulting in positive values for TCE and TCV, so that the magnitude of the original negative TCF of the SAW transducers is reduced. To achieve the best results, both thickness of the temperature compensation layer and deposition conditions should be controlled. For piezoelectric materials with positive intrinsic TCF values, temperature compensation layer other than SiO₂ should be used.

Hence, according to yet another embodiment of this invention as shown in FIG. 6C, an input SAW transducer (220) for devices such as SAW filters, SAW oscillators, switches and duplexers with elevated positive electrode doped regions and elevated negative electrode doped regions further comprising a temperature compensation layer (280) having a temperature compensation layer thickness (280t) deposited on the input inter digital transducer and the output inter digital transducer to minimize the shift of frequency due to the change or variation in temperature.

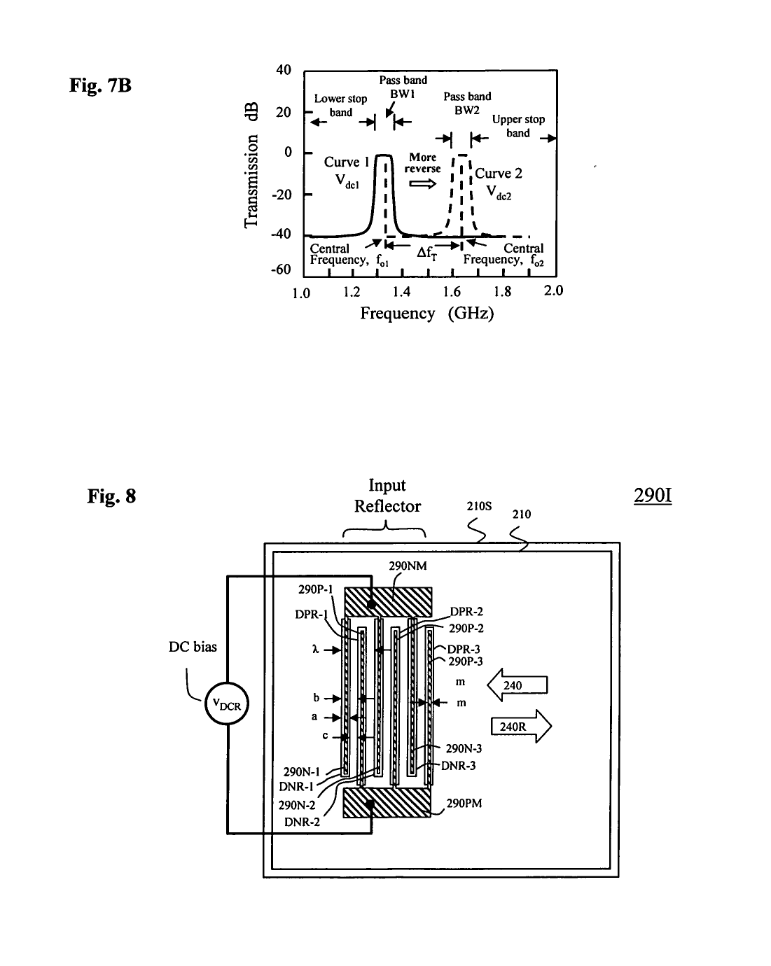

The effects of changes in the DC biasing voltage on the electric and acoustic properties of the present tunable IDTs are given in FIG. 7A. It shows schematically the change of impedance of an input inter digital transducer (IDT1) or an output inter digital transducer (IDT2) in a tunable SAW filter (200a in FIG. 2A), a tunable oscillator or any other tunable SAW devices according to this invention. This IDT could have embedded electrode doped regions as shown in FIGS. 2C-2I and FIGS. 4A-4C or elevated electrode doped regions as shown in FIGS. 5A-FIG. 5F and FIGS. 6A-6C. As described before, when the DC biasing voltage V_{DC} is varied in magnitude and/or in polarity, two effects will take place. The first one is the metallization ratio effect which will cause a MR frequency difference Δf_{MR}, due to changes in the electrode depletion region widths. Δf_{MR} is positive when MR increases and it is negative when MR decreases. This MR effect is relatively small especially in the IDTs with elevated electrode doped regions. The second effect is the mass loading effect which will cause a mass loading frequency difference Δf_{ML}, due to changes in the mass loading associated with the positive electrode fingers and the negative electrode fingers. Δf_{ML} is positive when ML decreases and it is negative when ML increases. Comparing to the MR effect (less than 5%), the ML effect is more prominent and is often as large as 20% or more than 30%.

The sum of Δf_{ML} and Δf_{MR} gives the combined total frequency change Δf_{T}. The impedance of an input inter digital transducer determines the frequency f of the surface acoustic waves to be excited, whereas the impedance of an output inter digital transducer determines the frequency of the surface acoustic waves to be detected or received. The above effects thus yield SAW input or output IDTs with tunable or adjustable surface acoustic wave frequencies according to this invention.

At a DC biasing voltage V_{DC1}, the variation of impedance of an IDT is given as Curve 1 in FIG. 7A, with a resonant frequency at fᵣ₁ and an anti-resonant frequency at fₐ₁ and a central frequency of transmission fₒ₁ in between fₐ₁ and fᵣ₁ for the surface acoustic filter. At a DC biasing voltage V_{DC2}, the variation of impedance is given as Curve 2, with the resonant frequency at fᵣ₂ and the anti-resonant frequency at fₐ₂ and the central frequency of transmission fₒ₂ in between fₐ₂ and fᵣ₂ for the surface acoustic wave filter (or oscillator) constructed. At a DC biasing voltage V_{DC3}, the variation of impedance is given by Curve 3 with resonant frequency at fᵣ₃ and anti-resonant frequency at fₐ₃ and the central frequency of transmission of the SAW filter fₒ₃ in between fₐ₃ and fᵣ₃. Therefore, a SAW resonator, an oscillator or a filter with the central frequency of transmission (or generation) adjustable and controllable by the polarity and magnitude of the DC biasing voltage V_{DC} is thus implemented using semiconducting piezoelectric layer with embedded or elevated electrode doped regions, according to this invention.

The transmission characteristics of a tunable SAW filter with tunable IDTs according to this invention is shown in FIG. 7B. It shows the shift and change of the transmission characteristics of a tunable SAW filter built using a tunable input inter digital transducer (IDT1) and a tunable output inter digital transducer (IDT2) shown in FIGS. 2A or 2B, having embedded electrode doped regions or elevated electrode doped regions according to this invention. When the DC biasing voltage V_{DC} is varied in magnitude and/or in polarity, metallization ratio effect and mass loading effect take place. At a DC biasing voltage V_{DC1}, the variation of transmission of the surface acoustic wave is given by Curve 1 in FIG. 7B with a central frequency of transmission fₒ₁ and a bandwidth BW1. As the DC biasing voltage is changed to V_{DC2}, which is more reverse biased, the variation of transmission of SAW is given by Curve 2 with the central frequency of transmission fₒ₂ and a bandwidth BW2. Hence, a surface acoustic waves filter or oscillator constructed with the IDTs in this invention will have a transmission frequency tunable and adjustable by the applied DC biasing voltages.

FIG. 8 shows a schematic top view of a surface acoustic wave (SAW) input reflector (290I) with tunable and adjustable frequency, according to this invention. It comprises a first piezoelectric layer (210) on a support substrate (210S); an input positive electrode pad (290PM) and an input negative electrode pad (290NM) which may be advantageously constructed on the first piezoelectric layer (210); a plurality of input positive electrode doped regions (DPR−1, DPR−2, DPR−3) which are doped piezoelectric semiconductor containing certain dopants; a plurality of metallic input positive electrode fingers (290P−1, 290P−2, 290P−3) each on one of the input positive electrode doped regions; a plurality of input negative electrode doped regions (DNR−1, DNR−2, DNR−3) which are doped piezoelectric semiconductor containing certain dopants; a plurality of metallic input negative electrode fingers (290N−1, 290N−2, 290N−3) each on one of the input negative electrode doped regions. In FIG. 8, the input positive electrode doped regions and the input negative electrode doped regions may be embedded or elevated.

By applying a DC biasing voltage V_{DCR} and adjusting and controlling the magnitude of V_{DCR} to control the metallization ratio and the mass loading associated with the positive and negative electrodes, the frequency of the surface acoustic waves to be reflected may be controlled to be the same as the frequency of the surface acoustic waves (240) excited by the input inter digital transducer IDT1 (220) and/or to be the same as the frequency of the SAW to be received by the output inter digital transducer IDT2 (250) in the SAW filters (200a in FIG. 2A and 200b in FIG. 2B). As a result of above tuning, when placed beside the input inter digital transducer IDT1 (220), majority of SAW waves (240) are reflected as reflected SAW waves (240R) and any unwanted loss of energy for the SAW wave is reduced. A SAW output reflector with tunable and adjustable frequency for the output inter digital transducer IDT2 may also be constructed with the same structure for the SAW input reflector (290I) to minimize loss of surface acoustic wave energy for receiving. When placed beside the output inter digital transducer IDT2 (250), any unwanted loss of energy for the surface acoustic wave to be received is reduced.

What is claimed is:

1. A frequency tunable SAW inter digital transducer IDT structure with embedded electrode doped regions for surface acoustic devices comprising
a support substrate with a support substrate thickness;
a first piezoelectric layer with a first piezoelectric layer thickness on said support substrate;
a plurality of positive electrode doped regions embedded in said first piezoelectric layer, said positive electrode doped regions are piezoelectric semiconductors having a first doping type;
a plurality of negative electrode doped regions embedded in said first piezoelectric layer, said negative electrode doped regions are piezoelectric semiconductors having a second doping type, wherein each said negative electrode doped region is between two adjacent positive electrode doped regions;
a plurality of metallic positive electrode fingers connected to a positive electrode pad, each said metallic positive electrode fingers on one of respective embedded positive electrode doped regions;
a plurality of metallic negative electrode fingers connected to a negative electrode pad, each said metallic negative electrode fingers on one of respective embedded negative electrode doped regions; and
a DC biasing voltage is connected to said IDT through blocking inductors to tune and adjust frequency of surface acoustic waves to be excited or to be received by said IDT through tuning and adjusting loading mass and metallization ratio associated with said positive electrode fingers and negative electrode fingers,
wherein a center-to-center distance between adjacent said positive electrode finger and said negative electrode finger or between adjacent said positive electrode doped region and said negative electrode doped region is controlled to a pitch b, whereas said positive electrode pad and negative electrode pad are connected to an electrical signal source or to a signal receiver to excite or receive surface acoustic waves.

2. A frequency tunable SAW inter digital transducer IDT structure with embedded electrode doped regions for surface acoustic devices as defined in claim 1, wherein material for said support substrate is selected from a material group including: LiNbO₃, LiTaO₃, PZT, AlN, GaN, AlGaN, ZnO, GaAs, AlAs, AlGaAs, Al₂O₃, BaTiO₃, quartz and KNbO₃, Si, sapphire, quartz, glass, and plastic.

3. A frequency tunable SAW inter digital transducer IDT structure with embedded electrode doped regions for surface acoustic devices as defined in claim 1, wherein material of said first piezoelectric layer is selected from a material group of piezoelectric materials including: LiNbO₃, LiTaO₃, ZnO, AlN, GaN, AlGaN, LiTaO₃, GaAs, AlGaAs and others, as long as they are piezoelectric and with sufficiently high coupling coefficient.

4. A frequency tunable SAW inter digital transducer IDT structure with embedded electrode doped regions for surface acoustic devices as defined in claim 1, wherein materials of said embedded positive electrode doped regions and said embedded negative electrode doped regions are selected from a group including: AlN, GaN, AlGaN, ZnO, GaAs, AlAs, AlGaAs and others, as long as they are piezoelectric with sufficient acoustic coupling coefficients and are semiconducting and can be doped to n-type or p-type conduction with a doping concentration preferably in a range of 10¹⁴ to 10²¹ cm⁻³ and more preferably in a range of 10¹⁵ to 10²⁰ cm⁻³.

5. A frequency tunable SAW inter digital transducer IDT structure with embedded electrode doped regions for surface acoustic devices as defined in claim 1, wherein said first doping type of said positive electrode doped regions is opposite to said second doping type of said negative electrode doped regions and said DC biasing voltage is applied between said positive electrode pad and said negative electrode pad through said blocking inductors to tune and adjust frequency of said surface acoustic waves.

6. A frequency tunable SAW inter digital transducer IDT structure with embedded electrode doped regions for surface acoustic devices as defined in claim 1, wherein thicknesses of said embedded positive electrode doped regions and said embedded negative electrode doped regions are controlled preferably to be in a range of 10 to 2000 nm and more preferably to be in a range of 20 to 1000 nm.

7. A frequency tunable SAW inter digital transducer IDT structure with embedded electrode doped regions for surface acoustic devices as defined in claim 1, wherein materials for said positive electrode fingers and said negative electrode fingers are selected from a group of: Ti, Al, W, Pt, Mo, Cr, Pd, Ta, Cu, Cr, Au, Ni, Ag, Ru, Ir and other metals and their alloys, whereas thicknesses of said positive electrode fingers and negative electrode fingers are selected preferably to be in a range of 10 to 400 nm and more preferably in a range of 20 to 300 nm, dependent on the operation frequency and the tuning range required.

8. A frequency tunable SAW inter digital transducer IDT structure with embedded electrode doped regions for surface acoustic devices as defined in claim 1, further comprising a temperature compensation layer with a temperature compensation layer thickness on said IDT to compensate and to minimize shift of frequency due to change of temperature.

9. A frequency tunable SAW inter digital transducer IDT structure with embedded electrode doped regions for surface acoustic devices as defined in claim 1, further comprising a bottom electrode layer sandwiched between said first piezoelectric layer and said support substrate, wherein said first doping type is the same as said second doping type and said DC biasing voltage is applied between said positive electrode pad, said negative electrode pad and said bottom electrode layer to tune and adjust frequency of said surface acoustic waves.

10. A frequency tunable SAW inter digital transducer IDT structure with embedded electrode doped regions for surface acoustic devices as defined in claim 1, further comprising a heavily doped layer on said embedded negative electrode doped regions and another heavily doped layer on said embedded positive electrode doped regions to reduce contact resistance.

11. A frequency tunable SAW inter digital transducer IDT structure with embedded electrode doped regions for surface acoustic devices as defined in claim 1, wherein said frequency tunable SAW inter digital structure is a tunable input inter digital transducer for receiving RF signals and producing surface acoustic waves.

12. A frequency tunable SAW inter digital transducer IDT structure with embedded electrode doped regions for surface acoustic devices in as defined in claim 1, wherein said frequency tunable SAW inter digital structure is a tunable output inter digital transducer for receiving surface acoustic waves and converting them to RF signals.

13. A frequency tunable SAW inter digital transducer IDT structure with embedded electrode doped regions for surface acoustic devices as defined in claim 1, wherein said frequency tunable SAW inter digital structure is a tunable reflector for surface acoustic waves.

14. A frequency tunable SAW inter digital transducer IDT structure with elevated electrode doped regions for surface acoustic devices comprising
a support substrate with a support substrate thickness;
a first piezoelectric layer with a first piezoelectric layer thickness;
a plurality of elevated positive electrode doped regions on said first piezoelectric layer, said elevated positive electrode doped regions are piezoelectric semiconductors having a first doping type;
a plurality of elevated negative electrode doped regions on said first piezoelectric layer, said negative electrode doped regions are piezoelectric semiconductors having a second doping type, wherein each said elevated negative electrode doped region is between two adjacent elevated positive electrode doped regions;
a plurality of metallic positive electrode fingers connected to a positive electrode pad, each said positive electrode fingers on one of respective elevated positive electrode doped regions;
a plurality of metallic negative electrode fingers connected to a negative electrode pad, each said negative electrode fingers on one of respective elevated negative electrode doped regions; and
a DC biasing voltage is connected said IDT through blocking inductors to tune and adjust the frequency of surface acoustic waves to be excited or to be received by said IDT through tuning and adjusting loading mass and metallization ratio associated with said positive electrode fingers and said negative electrode fingers,
wherein a center-to-center distance between adjacent said positive electrode finger and said negative electrode finger or between adjacent said elevated positive electrode doped region and said elevated negative electrode doped region is controlled to a pitch b, whereas said positive electrode pad and negative electrode pad are connected to an electrical signal source or to a signal receiver to excite or receive surface acoustic waves.

15. A frequency tunable SAW inter digital transducer IDT structure with elevated electrode doped regions for surface acoustic devices as defined in claim 14, wherein material for said support substrate is selected from a material group including: LiNbO₃, LiTaO₃, PZT, AlN, GaN, AIGaN, ZnO, GaAs, AlAs, AlGaAs, Al₂O₃, BaTiO₃, quartz and KNbO₃, Si, sapphire, quartz, glass, and plastic.

16. A frequency tunable SAW inter digital transducer IDT structure with elevated electrode doped regions for surface acoustic devices as defined in claim 14, wherein material of said first piezoelectric layer is selected from a material group of piezoelectric materials including: LiNbO₃, LiTaO₃, ZnO, AlN, GaN, AlGaN, LiTaO₃, GaAs, AlGaAs and others, as long as they arc piezoelectric and with sufficiently high coupling coefficient.

17. A frequency tunable SAW inter digital transducer IDT structure with elevated electrode doped regions for surface acoustic devices as defined in claim 14, wherein materials of said elevated positive electrode doped regions and said elevated negative electrode doped regions are selected from a group including: AlN, GaN, AlGaN, ZnO, GaAs, AlAs, AlGaAs and others, as long as they are piezoelectric with sufficient acoustic coupling coefficients and are semiconducting and can be doped to n-type or p-type conduction with a doping concentration preferably in a range of 10¹⁴ to 10²¹ cm⁻³ and more preferably in a range of 10¹⁵ to 10²⁰ cm⁻³.

18. A frequency tunable SAW inter digital transducer IDT structure with elevated electrode doped regions for surface acoustic devices as defined in claim 14, wherein said first doping type of said elevated positive electrode doped regions is opposite to said second doping type of said elevated negative electrode doped regions and said DC biasing voltage is applied between said positive electrode pad and said negative electrode pad through said blocking inductors to tune and adjust frequency of said surface acoustic waves.

19. A frequency tunable SAW inter digital transducer IDT structure with elevated electrode doped regions for surface acoustic devices as defined in claim 14, wherein thicknesses of said elevated positive electrode doped regions and said elevated negative electrode doped regions are controlled preferably to be in a range of 10 to 2000 nm and more preferably to be in a range of 20 to 1000 nm.

20. A frequency tunable SAW inter digital transducer IDT structure with elevated electrode doped regions for surface acoustic devices as defined in claim 14, wherein materials for said positive electrode fingers and said negative electrode fingers are selected from a group of: Ti, Al, W, Pt, Mo, Cr, Pd, Ta, Cu, Cr, Au, Ni, Ag, Ru, Ir and other metals and their alloys, whereas thickness of said positive electrode fingers and said negative electrode fingers is selected to be in a range of 10 to 400 nm and is more preferably in a range of 20 to 300 nm, dependent on the operation frequency and the tuning range required.

21. A frequency tunable SAW inter digital transducer IDT structure with elevated electrode doped regions for surface acoustic devices as defined in claim 14, further comprising a temperature compensation layer with a temperature compensation layer thickness on said inter digital transducers to compensate and to minimize shift of frequency due to change of temperature.

22. A frequency tunable SAW inter digital transducer IDT structure with elevated electrode doped regions for surface acoustic devices as defined in claim 14, further comprising a bottom electrode layer sandwiched between said first piezoelectric layer and said support substrate, wherein said first doping type is the same as said second doping type and said DC biasing voltage is applied between said positive electrode pad, said negative electrode pad and said bottom electrode layer to tune and adjust frequency of said surface acoustic waves.

23. A frequency tunable SAW inter digital transducer IDT structure with elevated electrode doped regions for surface acoustic devices as defined in claim 14, further comprising a heavily doped layer on said elevated negative electrode doped regions and another heavily doped layer on said elevated positive electrode doped regions to reduce contact resistance.

24. A frequency tunable SAW inter digital transducer IDT structure with elevated electrode doped regions for surface acoustic devices as defined in claim 14, wherein said frequency tunable SAW inter digital structure is a tunable input inter digital transducer for receiving RF signals and producing surface acoustic waves.

25. A frequency tunable SAW inter digital transducer IDT structure with elevated electrode doped regions for surface acoustic devices in as defined in claim 14, wherein said frequency tunable SAW inter digital structure is a tunable output inter digital transducer for receiving surface acoustic waves and converting them to RF signals.

26. A frequency tunable SAW inter digital transducer IDT structure with elevated electrode doped regions for surface acoustic devices as defined in claim 14, wherein said frequency tunable SAW inter digital structure is a tunable reflector for surface acoustic waves.
